(19) United States
(12) Patent Application Publication
(10) Pub. No.: US 2009/0251652 A1
(43) Pub. Date: Oct. 8, 2009

(54) Silica based positive type photosensitive organic compound

(75) Inventors: Kyoko Kojima, Kunitachi (JP); Koichi Abe, Takahagi (JP)

Correspondence Address: Juan Carlos A. Marquez;c/o Stites & Harbison PLLC, 1199 North Fairfax Street, Suite 900, Alexandria, VA, 22314-1437, US

(73) Assignee: Hitachi Chemical Co., Ltd.

(21) Appl. No.: 12/379,365

(22) Filed: Feb. 19, 2009

(30) Foreign Application Priority Data
Mar. 31, 2008 (JP) 2008-089632

(51) Int. Cl. G02F 1/1333; G03F 7/004; G03F 7/20

(52) U.S. Cl. 349/138; 430/270.1; 430/281.1; 430/320

(57) ABSTRACT

A material for a dielectric film used in a flat display or the like having a positive type photosensitivity containing:
an ingredient (a): a siloxane resin soluble in aqueous alkaline solution obtained by hydrolysis-condensation of a compound represented by the following general formula (1):

R¹OCOASiX₃ (1)

(in which R¹ and A each represent an organic group and X represents a hydrolyzable group),
an ingredient (b): a dissolution inhibitory compound,
an ingredient (c): an acid generator which is a compound generating an acid by the irradiation of a light or an electron beam, and
an ingredient (d): a solvent capable of dissolving the ingredient (a), each of the ingredients including at least one member respectively in which the blending ratio of the ingredient (a) in the composition is from 5 to 50% by weight.

### CLAIM OF PRIORITY

The present application claims priority from Japanese Patent Application JP 2008-089632 filed on Mar. 31, 2008, the content of which is hereby incorporated by reference into this application.

### BACKGROUND OF THE INVENTION

1. Field of the Invention

The present invention concerns a positive type photosensitive resin composition suitable as a material for forming a protection film, a dielectric, etc. used, for example, for electronic parts and, particularly, a material for forming an inter-layer dielectric in a flat display device such as a liquid crystal device, a method of forming a patterned dielectric using the same, and a semiconductor device, a flat display device having an active matrix substrate and an electronic device having an dielectric using the positive type photosensitive resin composition.

2. Description of the Related Art

In the manufacture of a semiconductor device or a liquid crystal display device, an inter-layer dielectric is used. Generally, the inter-layer dielectric is coated or deposited from a vapor phase and then patterned by being etched by way of a photoresist. In a case of a fine pattern, vapor phase etching is used for the etching. However, the vapor phase etching involves a problem that the cost of apparatus is high and the processing speed is slow, and a photosensitive inter-layer dielectric material has been developed with an aim of decreasing the process cost.

Particularly, in the liquid display device, since it is necessary to form a contact hole in a transparent inter-layer dielectric used for insulation between a pixel electrode and a gate/drain wiring and planarization of the device, a positive type photosensitive inter-layer dielectric material having a positive type photosensitivity has been demanded. Further, in a case of using the patterned deposition film while leaving the same as an inter-layer dielectric, it is desired that the deposition film has a low dielectric constant.

For coping with such a demand, JP-A No. 2000-181069 discloses a method of forming a patterned polysilazane film that includes a step of forming a coating film of a photosensitive polysilazane composition containing a polysilazane and a photo acid generator, a step of irradiating a light patternwise to the coating film, and a step of dissolving to remove the irradiated portion of the coating film, and a method of forming a patterned dielectric film that includes a step of hydrolyzing and baking the patterned polysilazane film thereby transforming the same into a silica based ceramic deposition film.

Further, as the positive type photosensitive inter-layer dielectric material, JP-A No. 2004-107562 describes a composition including a transparent acrylic resin and a diazonaphthoquinone (DNQ) as a photosensitive agent.

As means for improving the transparency of the inter-layer dielectric material, a method adopted in a photosensitive material (photoresist) for fine fabrication of a semiconductor described, for example, in WO 2007/094784A1 has been known.

In the method of using the polysilazane described in JP-A No. 2000-181069, it is necessary to transform from a polysilazane structure to a polysiloxane structure by a hydrolysis reaction after the patterning step by exposure and development. When the water content in the film is insufficient during the hydrolysis reaction step, it results in a problem that the reaction does not proceed sufficiently. Further, in the hydrolysis reaction of the polysilazane compound, highly volatile ammonia evolves to result in a problem of causing toxicity and corrosion in production apparatus.

Further, for the method of using the composition including the acrylic resin and diazonaphthoquinone (DNQ) as the photosensitive agent described in JP-A No. 2004-107562, it has been known that the dielectric film can be made transparent when the photosensitive agent DNQ which is originally colored is completely decomposed by entire exposure after development. However, since the heat resistance temperature of the acrylic resin is about 230° C. and this is not sufficient, degradation reaction of a base resin occurs during various steps after patterning to result in coloration or denaturation.

The method of using a chemical amplification type material described in WO 2007/094784A1 involves a problem that heat resistance is not insufficient when the material is used alone and denaturation such as deformation occurs in various steps after patterning.

Accordingly, the present invention intends at first to provide a positive type photosensitive resin composition having sufficient photosensitivity, and excellent in insulation property, low dielectric property, heat resistance, and increase of film thickness.

The invention further intends to provide a silica based deposition film forming composition capable of easily forming a silica based deposition film excellent in the insulation property, the low dielectric property, the heat resistance, and the increase of film thickness, and excellent in transparency depending on the case.

The invention still further intends to provide a flat display or an electronic part of high quality and excellent in the reliability.

### SUMMARY OF THE INVENTION

For overcoming the problems described above, the present invention has the following typical constitution:

A silica based positive type photosensitive resin composition at least containing:

an ingredient (a): a siloxane resin soluble in aqueous alkaline solution containing a compound represented by R¹OCOASiX₃ (where R¹ and A represent each an organic group and X represents a hydrolyzable group),

an ingredient (b): a dissolution inhibitory compound having a functional group that can be decomposed by the action of an acid and increasing the solubility to an alkaline developer by the action of the acid,

an ingredient (c): an acid generator which is a compound of generating an acid by the irradiation of a light or an electron beam, and

an ingredient (d): a solvent capable of dissolving the ingredient (a), in which the blending ratio of the ingredient (a) based on the composition is from 5 to 50% by weight. Details for each of the ingredients in the invention are as described below.

### Ingredient (a)

In the silica based positive type photosensitive resin composition of the invention, the siloxane resin of the ingredient (a) soluble in aqueous alkaline solution includes a siloxane resin obtained by hydrolysis-condensation of a compound of R¹OCOASiX₃ (in which R¹ and A represent each an organic group and X represents a hydrolyzable group) and a compound represented by R²SiX₃ (in which R² represents an aromatic group or an alicyclic hydrocarbon group, or an organic group having 1 to 20 carbon atoms, and X represents a hydrolyzable group).

Further, the silica based positive type photosensitive resin composition of the invention is formed by mixing the siloxane resin of the ingredient (a) soluble in aqueous alkaline solution and, further, a resin obtained by hydrolysis-condensation of a compound represented by R³ₙSiX₄₋ₙ (in which R³ represents a group containing an H atom, an F atom, a B atom, an N atom, an Al atom, a P atom, an Si atom, a Ge atom, or Ti atom, or an organic group having 1 to 20 carbon atoms, X represents a hydrolyzable group, and n represents an integer of 0 to 2, and each of R³ may be identical or different at n=2, and each X may be identical or different at n=0 to 2.

### Ingredient (b)

In the invention, the dissolution inhibitory compound has a functional group that can be decomposed by the action of an acid and increases the solubility to an alkaline developer by the action of the acid.

The functional group that can be decomposed by the action of the acid in the dissolution inhibitory compound of the ingredient (b) is a protection carboxyl group represented by the following general formula (8).

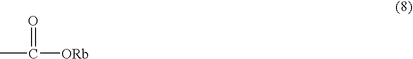

(in the general formula (8), Rb represents a dissolution inhibitory group, which is a functional group selected from tetrahydropyranyl group, tetrahydrofranyl group, methoxyethoxymethyl group, benzoyloxymethyl group, t-butyl group, dicyclopropyl methyl group, 2,4-dimethyl 3-pentyl group, cyclopentyl group, cyclohexyl group, p-methoxybenzyl group, trimethyl silyl group, triethyl silyl group-, t-butyl dimethyl silyl group, t-butyl diphenyl silyl group, triisopropyl silyl group, methyl carbonate group, 1-adamantyl carbonate group, t-butyl carbonate group (t-BOC group), and allylvinyl carbonate group).

Alternatively, in the silica-based positive photosensitive resin composition of the invention, the functional group that can be decomposed by the action of the acid in the dissolution inhibitory compound of the ingredient (b) is a protection carboxyl group represented by the following general formula (41).

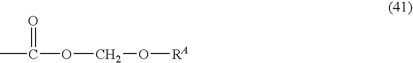

(in the general formula (41), R^{A} is a functional group selected from substituted or not-substituted linear or branched alkyl groups having 1 to 30 carbon atoms, and substituted or not-substituted cycloalkyl groups having 1 to 30 carbon atoms). The substituted or not-substituted cycloalkyl group having 1 to 30 carbon atoms is represented by the following general formula (42).

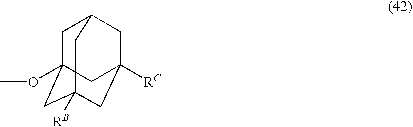

(in the general formula (42), R^{B} and R^{C} are functional groups each selected from a hydrogen atom, a hydroxyl group, and alkyl ethers having 1 to 30 carbon atoms).

Further, the functional group that can be decomposed by the action of the acid in the dissolution inhibitory compound of the ingredient (b) is bonded to the compound of the following general formula (43).

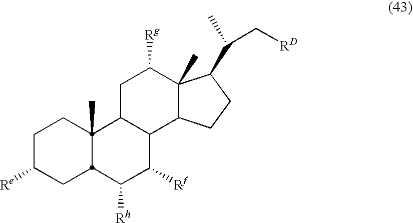

(in the general formula (43), R^{e} is a functional group represented by the general formula (41) that can be decomposed by the action of the acid (in the general formula (41), R^{A} is a functional group selected from substituted or not-substituted linear or branched alkyl groups having 1 to 30 carbon atoms and substituted or not-substituted cycloalkyl groups having 1 to 30 carbon atoms)), R^{e}, R^{f}, R^{g} are functional groups each selected from a hydrogen atom, a hydroxyl group, alkyl ether groups having 1 to 10 carbon atoms, and an acetoxy ether group).

The functional group that can be the decomposed by the action of the acid in the dissolution inhibitory compound of the ingredient (b) is a protecting phenol group represented by the following general formula (7).

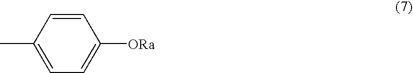

(in which Ra represents a dissolution inhibitory group, which is a functional group selected from methoxymethyl group, benzoyloxymethyl group, methoxyethoxymethyl group, 2-(trimethyl silyl)ethoxymethyl group, methylthiomethyl group, tetrahydropyranyl group, 1-ethoxyethyl group, phenacyl group, cyclopropylmethyl group, isopropyl group, cyclohexyl group, t-butyl group, trimethyl silyl group, t-butyl dimethylsilyl group, t-butyl diphenyl silyl group, triisopropyl silyl group, methyl carbonate group, 1-adamantyl carbonate group, t-butyl carbonate group (t-BOC group), and allylvinyl carbonate group.)

Further, in the silica based positive type photosensitive resin composition of the invention, the dissolution inhibitory compound of the ingredient (b) is a compound having an adamantyl group having a molecular weight of from 200 to 2000.

### Ingredient (c)

The invention provides a silica based positive type photosensitive resin composition containing at least one acid generator that is a compound generating an acid by the irradiation of a light or an electron beam.

Further, in the silica based positive photosensitive resin composition of the invention, the acid generator of the ingredient (c) is an acid generator generating a hydrohalogenic acid or a sulfonic acid by the irradiation of a light.

### Ingredient (d)

In the silica based positive type photosensitive resin type composition of the invention, the solvent capable of dissolving the ingredient (a) includes one or more solvents selected from the group consisting of ether acetate solvents, ether solvents, acetate solvents, alcohol solvents, and ketone solvents.

Further, the invention provides, in another aspect, a method of forming a silica based dielectric deposition film above a substrate, which is a method of forming a silica based dielectric deposition film obtained by forming a coating film by coating on the substrate, removing an organic solvent contained in the coating film, then removing the deposition film at an exposed region by performing exposure and development by way of a pattern mask to the deposition film and, subsequently, heat treating the remaining deposition film. Further, the invention also relates to a method of forming a silica based dielectric deposition film of further performing exposure after removing the deposition film from the exposed region and heat treating a residual deposition film.

The invention uses, in a further aspect, the dielectric film excellent in the transparency and of small dielectric constant in which through hole can be formed by a simple process, as a planarizing film, an organic passivation film, or an inter-layer dielectric for a flat display device or an electronic part.

The silica based positive type photosensitive resin composition of the invention can provide a silica based deposition film excellent in the photosensitivity, insulation property, low dielectric property, heat resistance, increase of film thickness, and transparence, and is useful as a material for a semiconductor device, a flat display device, and an electronic device. Particularly, when it is used for a flat display device, a high quality flat display device which is bright and with no color shift can be attained.

### DESCRIPTION OF THE ACCOMPANYING DRAWINGS

FIG. 1 is a plan view for a liquid crystal display device using a radiation sensitive composition of the invention;

FIG. 2 is a cross sectional view for a pixel of a liquid crystal display device using a radiation sensitive composition of the invention;

FIG. 3 is a cross sectional view for a pixel portion of an organic EL display device; and

FIG. 4 is a schematic cross sectional view showing a preferred embodiment of an electronic part according to the invention.

### DESCRIPTION OF PREFERRED EMBODIMENTS OF THE INVENTION

Preferred embodiments of the invention are to be described below.

### (Ingredient (a))

The siloxane resin soluble in an aqueous alkaline solution as the ingredient (a) in the invention contains a compound containing an acyloxy group represented by the following general formula (1) as the essential ingredient:

R¹OCOASiX₃ (1)

in which R¹ and A each represent an organic group and X represents a hydrolyzable group.

By containing the acyloxy group in the siloxane resin, a deposition film excellent in the photosensitivity and the property of dielectric deposition film can be obtained. Since the acyloxy group is easily soluble in an aqueous alkaline solution, the solubility is increased to the aqueous alkaline solution which is used upon development after exposure, contrast between a not-exposed region and an exposed region is increased to improve resolution. Further, since this is a soft and flexible ingredient, cracks are less induced in the deposition film after a heating treatment to facilitate increase of the film thickness.

Preferred examples of the organic group represented by R¹ include linear, branched, or cyclic hydrocarbon groups having 1 to 20 carbon atoms. The linear hydrocarbon group having 1 to 20 carbon atoms includes hydrocarbon groups such as a methyl group, an ethyl group, an n-propyl group, an n-butyl group, and an n-pentyl group. The branched hydrocarbon group includes hydrocarbon groups such as an iso-propyl group, and an iso-butyl group.

Further, the cyclic hydrocarbon group includes cyclic hydrocarbon groups such as a cyclopentyl group, a cyclohexyl group or a cycloheptylene group, or a bridged cyclic hydrocarbon groups such as those having a norbornane backbone and an adamantane backbone. Among the organic groups, linear hydrocarbon groups having 1 to 5 carbon atoms such as a methyl group, an ethyl group, and a propyl group are more preferred and the methyl group is particularly preferred with a view point of the availability of the starting material.

The organic group represented by A includes linear, branched, or cyclic hydrocarbons having 1 to 20 carbon atoms. Preferred hydrocarbon group includes, for example, hydrocarbon groups such as a methylene group, an ethylene group, a propylene group, a butylenes group, and a pentylene group as the linear hydrocarbon groups having 1 to 20 carbon atoms. The branched hydrocarbon groups include hydrocarbon groups such as an isopropylene group and an isobutylene group.

The cyclic hydrocarbon group includes cyclic hydrocarbon groups such as a cyclopentylene group, a cyclohexylene group, and a cycloheptylene group and a bridged cyclic hydrocarbon groups having, for example, a norbornane group. Among the hydrocarbon groups, linear hydrocarbon groups having 1 to 7 carbon groups such as a methylene group, an ethylene group, and a propylene group, a cyclic hydrocarbon groups such as a cyclopentylene group and a cyclohexylene group, and bridged cyclic hydrocarbon groups such as a norbornane are particularly preferred.

The hydrolyzable group X includes, for example, an alkoxy group, a halogen atom, an acetoxy group, an isocyanate group, and a hydroxyl group. Among them, the alkoxy group is preferred with a view point of the liquid stability, the coating property, etc. of the composition per se.

Further, a deposition film of excellent heat resistance can be obtained by using, together with the compound of the general formula (1) described above, a compound represented by the general formula (2) alone or in combination of two or more of such compounds:

R²SiX₃ (2)

in which R² represents an aromatic or alicyclic hydrocarbon group or an organic group having 1 to 20 carbon atoms, and X represents a hydrolyzable group. The aromatic hydrocarbon group represented by R² includes aromatic hydrocarbon groups such as a phenyl group, a naphthyl group, an anthracenyl group, a phenanthrenyl group, and a pyrenyl group.

Further, the alicyclic hydrocarbon group includes, for example, a cyclopentyl group, a cyclohexyl group, a norbornenyl group, and an adamantyl group.

With a view point of the thermal stability and the availability of the starting material, a phenyl group, a naphthyl group, a norbornenyl group, and an adamantyl group are more preferred.

Further, the organic group having 1 to 20 carbon atoms includes linear hydrocarbon groups such as a methyl group, an ethyl group, an n-propyl group, an n-butyl group, and an n-pentyl group, and branched hydrocarbon groups such as an iso-propyl group, and an iso-butyl group. With a view of the thermal stability and the availability of the starting material, hydrocarbon groups such as a methyl group, an ethyl group, and a propyl group are preferred.

The structure of the siloxane resin soluble in the aqueous alkaline solution including the compounds, for example, of the general formulae (1) and (2) is shown by the following general formula (31).

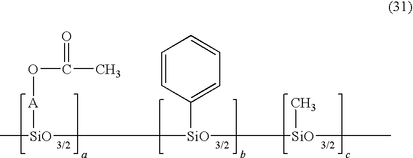

in which a, b, c each represent mol % where a is 1 to 99 mol %, b is 1 to 99 mol %, and c is 1 to 99 mol %, providing that a+b+c=100.

The amount of water used upon hydrolysis-condensation of the compounds represented by the general formulae (1) and (2) is preferably from 0.01 to 1000 mol and more preferably from 0.05 to 100 mol per 1 mol of the compound represented by the general formula (1). When the amount of water is less than 0.01 mol, the hydrolysis-condensation reaction does not tend to proceed sufficiently. When the amount of water is more than 1000 mol, a gelled product tends to be formed during hydrolysis or condensation.

Further, in the hydrolysis-condensation of the compounds represented by the general formulae (1) and (2), it is also preferred to use a catalyst. Such a catalyst includes, for example, acid catalysts, basic catalysts, and metal chelate compounds. Since the acyloxy group is sensitive to a basic condition, hydrolysis-condensation is performed particularly preferably under an acidic condition.

The acid catalyst includes, for example, organic acids and inorganic acids. The organic acid includes, for example, formic acid, maleic acid, fumaric acid, phthalic acid, malonic acid, succinic acid, tartaric acid, malic acid, lactic acid, citric acid, acetic acid, propionic acid, butanoic acid, pentanoic acid, hexanoic acid, heptanoic acid, octanoic acid, nonanoic acid, decanoic acid, oxalic acid, adipic acid, sebasic acid, butyric acid, oleic acid, stearic acid, linolic acid, linolenic acid, salicylic acid, benzene sulfonic acid, benzoic acid, p-aminobenzoic acid, p-toluene sulfonic acid, methane sulfonic acid, trifluoromethane sulfonic acid, and trifluoroethane sulfonic acid. The inorganic acid includes, for example, hydrochloric acid, phosphoric acid, nitric acid, boric acid, sulfuric acid, and hydrofluoric acid. They may be used each alone or two or more of them may be used in combination.

In the hydrolysis-condensation, hydrolysis is performed preferably by using the catalyst but it may be a possibility of worsening the stability of the composition or giving undesired effects such as corrosion on other materials by the containment of the catalyst. In such a case, the catalyst may be removed from the composition or may be reacted with other compounds to deactivate the catalystic function after hydrolysis. There is no particular restriction for the removing method or the reaction method, and the catalyst may be removed by distillation or using an ion chromatography. Further, the hydrolyzates obtained from the compounds represented by the general formulae (1) and (2) may also be taken out of the composition by re-precipitation or the like.

The amount of the catalyst to be used is preferably within a range from 0.0001 to 1 mol based on 1 mol of the compound. When the amount of use is less than 0.0001 mol, the reaction does not tend to proceed substantially. On the other hand, when it is more than 1 mol, gelation tends to be accelerated upon hydrolysis-condensation. Further, since an alcohol by-produced by the hydrolysis is a protic solvent, it is preferably removed by using an evaporator or the like.

With a view point of dissolution to the solvent, moldability, etc. the thus obtained siloxane resin has a weight average molecular weight of preferably 500 to 1,000,000, more preferably 500 to 500,000, further preferably 500 to 100,000, and particularly preferably 500 to 50,000. When the weight average molecular weight is less than 500, deposition property of the silica based deposition film tends to be deteriorated. On the other hand, when the weight average molecular weight is more than 1,000,000, compatibility with the solvent tends to be deteriorated.

In the present specification, the weight average molecular weight is measured by gel permeation chromatography (hereinafter referred to as “GPC”) and converted by using a calibration curve of a standard polystyrene.

The weight average molecular weight (Mw) can be measured, for example, by GPC under the following conditions.

Specimen: Silica based deposition film forming composition 10 μL

Standard polystyrene: Standard polystyrene manufactured by Tohso Corp. (molecular weight: 190000, 17900, 9100, 2980, 578, 474, 370, 266)

Detector: RI-monitor, trade name of product “L-3000” manufactured by Hitachi Ltd.,

Integrator: GPC integrator, trade name of product “D-2200” manufactured by Hitachi Ltd.,

Pump: trade name of product, “L-6000” manufactured by Hitachi Ltd.,

Degassing apparatus: trade name of product “Shodex DEGAS” manufactured by Showa Denko K.K.,

Column: trade name of product, “GL-R440” “GL-R430” and “GL-R420” manufactured by Hitachi Chemical Industry Co., are used being connected in this order.

Eluent: Tetrahydrofuran (THF)

Measuring temperature: 23° C.

Flow rate: 1.75 mL/min

Measuring time: 45 min

The blending ratio of the ingredient (a) in the composition is preferably from 5 wt % to 50 wt %, more preferably from 7 wt % to 40 wt %, further preferably from 10 wt % to 40 wt %, and particularly preferably from 15 wt % to 35 wt % with a view point of the solubility, the film thickness, the moldability, and the stability of the solution. When the blending ratio is less than 5 wt %, the film deposition property of the silica based deposition film tends to be deteriorated. When it is more than 50 wt %, the stability of the solution tends to be lowered.

Further, the strength of the deposition film can be improved by mixing the siloxane resin of the ingredient (a) soluble in aqueous alkaline solution and a resin obtained by hydrolysis-condensation of the compound represented by the following general formula (3):

R³ₙSiX₄₋ₙ (3)

in which R³ represents a group containing an H atom, an F atom, a B atom, an N atom, an Al atom, a P atom, an Si atom, a Ge atom, or a Ti atom, or an organic group having 1 to 20 carbon atoms, X represents a hydrolyzable group, n represents an integer of 0 to 2, each R¹ may be identical or different at n=2, and each X may be identical or different at n=0 to 2.

The hydrolyzable group X includes, for example, an alkoxy group, a halogen atom, an acetoxy group, an isocyanate group, and a hydroxyl group. Among them, the alkoxy group is preferred with a view point of the liquid stability, coating property, etc. of the composition per se.

The compound of the general formula (3) in which the hydrolyzable group X is the alkoxy group (alkoxy silane) includes, for example, tetraalkoxysilane, trialkoxysilane, and diorganodialkoxysilane.

The tetraalkoxysilane includes, for example, tetramethoxysilane, tetraethoxysilane, tetra-n-propoxysilane, tetra-iso-propoxysilane, tetra-n-butoxysilane, tetra-sec-butoxysilane, tetra-tert-butoxylsilane, and tetraphenoxysilane.

The trialkoxysilane includes, for example, trimethoxysilane, triethoxysilane, tripropoxysilane, fluorotrimethoxysilane, fluorotriethoxysilane, methyl trimethoxysilane, methyl triethoxysilane, methyl tri-n-propoxysilane, methyl tri-iso-propoxysilane, methyl tri-n-butoxysilane, methyl tri-iso-butoxysilane, methyl tri-tert-butoxysilane, methyl triphenoxysilane, ethyl trimethoxysilane, ethyl triethoxysilane, ethyl tri-n-propoxysilane, ethyl tri-iso-propoxysilane, ethyl tri-n-butoxysilane, ethyl tri-iso-butoxysilane, ethyl tri-tert-butoxysilane, ethyl triphenoxysilane, n-propyl trimethoxysilane, n-propyl triethoxysilane, n-propyl tri-n-propoxysilane, n-propyl tri-iso-propoxysilane, n-propyl tri-n-butoxysilane, n-propyl tri-iso-butoxysilane, n-propyl tri-tert-butoxysilane, n-propyl triphenoxysilane, iso-propyl trimethoxysilane, iso-propyl triethoxysilane, iso-propyl tri-n-propoxysilane, iso-propyl tri-iso-propoxysilane, iso-propyl tri-n-butoxysilane, iso-propyl tri-iso-butoxysilane, iso-propyl tri-tert-butoxysilane, iso-propyl triphenoxysilane, n-butyl trimethoxysilane, n-butyl triethoxysilane, n-butyl tri-n-propoxysilane, n-butyl tri-iso-propoxysilane, n-butyl tri-n-butoxysilane, n-butyl tri-iso-butoxysilane, n-butyl tri-tert-butoxysilane, n-butyl triphenoxysilane, sec-butyl trimethoxysilane, sec-butyl triethoxysilane, sec-butyl tri-n-propoxysilane, sec-butyl tri-iso-propoxysilane, sec-butyl tri-n-butoxysilane, sec-butyl tri-iso-butoxysilane, sec-butyl tri-tert-butoxysilane, sec-butyl triphenoxysilane, t-butyl trimethoxysilane, t-butyl triethoxysilane, t-butyl tri-n-propoxysilane, t-butyl tri-iso-propoxysilane, t-butyl tri-n-butoxysilane, t-butyl tri-iso-butoxysilane, t-butyl tri-tert-butoxysilane, t-butyl triphenoxysilane, phenyl trimethoxysilane, phenyl triethoxysilane, phenyl tri-n-propoxysilane, phenyl tri-iso-propoxysilane, phenyl tri-n-butoxysilane, phenyl tri-iso-butoxysilane, phenyl tri-tert-butoxysilane, phenyl triphenoxysilane, trifluoromethyl trimethoxysilane, pentafluoroethyl trimethoxysilane, 3,3,3-trifluoropropyl trimethoxysilane, and 3,3,3-trifluoropropyl triethoxysilane.

The diorganodialkoxysilane includes, for example, dimethyl dimethoxysilane, dimethyl diethoxysilane, dimethyl di-n-propoxysilane, dimethyl di-iso-propoxysilane, dimethyl di-n-butoxysilane, dimethyl di-sec-butoxysilane, dimethyl di-tert-butoxysilane, dimethyl diphenoxysilane, diethyl dimethoxysilane, diethyl diethoxysilane, diethyl di-n-propoxysilane, diethyl di-iso-propoxysilane, diethyl di-n-butoxysilane, diethyl di-sec-butoxysilane, diethyl di-tert-butoxysilane, diethyl diphenoxysilane, di-n-propyl dimethoxysilane, di-n-propyl diethoxysilane, di-n-propyl di-n-propoxysilane, di-n-propyl di-iso-propoxysilane, di-n-propyl di-n-butoxysilane, di-n-propyl di-sec-butoxysilane, di-n-propyl di-tert-butoxysilane, di-n-propyl diphenoxysilane, di-iso-propyl dimethoxysilane, di-iso-propyl diethoxysilane, di-iso-propyl di-n-propoxysilane, di-iso-propyl di-iso-propoxysilane, di-iso-propyl di-n-butoxysilane, di-iso-propyl di-sec-butoxysilane, di-iso-propyl di-tert-butoxysilane, di-iso-propyl diphenoxysilane, di-n-butyl dimethoxysilane, di-n-butyl diethoxysilane, di-n-butyl di-n-propoxysilane, di-n-butyl di-iso-propoxysilane, di-n-butyl di-n-butoxysilane, di-n-butyl di-sec-butoxysilane, di-n-butyl di-tert-butoxysilane, di-n-butyl diphenoxysilane, di-sec-butyl dimethoxysilane, di-sec-butyl diethoxysilane, di-sec-butyl di-n-propoxysilane, di-sec-butyl di-iso-propoxysilane, di-sec-butyl di-n-butoxysilane, di-sec-butyl di-sec-butoxysilane, di-sec-butyl di-tert-butoxysilane, di-sec-butyl diphenoxysilane, di-tert-butyl dimethoxysilane, di-tert-butyl diethoxysilane, di-tert-butyl di-n-propoxysilane, di-tert-butyl di-iso-propoxysilane, di-tert-butyl di-n-butoxysilane, di-tert-butyl di-sec-butoxysilane, di-tert-butyl di-tert-butoxysilane, di-tert-butyl diphenoxysilane, di-phenyl dimethoxysilane, diphenyl diethoxysilane, diphenyl di-n-propoxysilane, diphenyl di-iso-propoxysilane, diphenyl di-n-butoxysilane, diphenyl-di-sec-butoxysilane, diphenyl-tert-butoxysilane, diphenyl diphenoxysilane, bis(3,3,3-trifluoropropyl)dimethoxysilane, and methyl(3,3,3-trifluoropropyl)dimethoxysilane.

In the compound of the general formula (3) in which R³ is the organic group having 1 to 20 carbon atoms, compounds other than those described above include, for example, bis-silyl alkanes and bis-silyl benzenes such as bis(trimethoxysilyl)methane, bis(triethoxysilyl)methane, bis(tri-n-propoxysilyl)methane, bis(tri-iso-propoxysilyl)methane, bis(trimethoxysilyl)ethane, bis(triethoxysilyl)ethane, bis(tri-n-propoxysilyl)ethane, bis(tri-iso-propoxysilyl)ethane, bis(trimethoxysilyl)propane, bis(triethoxysilyl)propane, bis(tri-n-propoxysilyl)propane, bis(tri-iso-propoxysilyl)propane, bis(trimethoxysilyl)benzene, bis(triethoxysilyl)benzene, bis(tri-n-propoxysilyl)benzene, and bis(tri-iso-propoxysilyl)benzene.

Further, the compound of the general formula (3) in which R³ is the group containing the Si atom includes, for example, hexaalkoxydisilanes such as hexamethoxydisilane, hexaethoxydisilane, hexa-n-propoxydisilane, and hexa-iso-propoxydisilane, and dialkyl tetraalkoxydisilanes such as 1,2-dimethyl tetramethoxydisilane, 1,2-dimethyl tetraethoxydisilane, and 1,2-dimethyl tetrapropoxydisilane.

The compound represented by the general formula (3) is used alone or two or more of such compounds are used in combination. The amount of water used upon hydrolysis-condensation of the compound represented by the general formula (3) is preferably from 0.1 to 1000 mol, and more preferably from 0.5 to 100 mol based on 1 mol of the compound represented by the general formula (3). When the amount of water is less than 0.1 mol, the hydrolysis-condensation reaction does not tend to proceed sufficiently and, when the amount of water is more than 1000 mol, gelled product tends to be formed during hydrolysis or condensation.

Further, in the hydrolysis-condensation of the compound represented by the general formula (3), use of a catalyst is preferred. The catalyst includes, for example, acid catalysts, basic catalysts, and metal chelate compounds, and the acid catalyst is particularly preferred with a view point of the stability of the solution.

The acid catalyst includes, for example, organic acids and inorganic acids. The organic acid includes, for example, formic acid, maleic acid, fumaric acid, phthalic acid, malonic acid, succinic acid, tartaric acid, malic acid, lactic acid, citric acid, acetic acid, propionic acid, butanoic acid, pentanoic acid, hexanoic acid, heptanoic acid, octanoic acid, nonanoic acid, decanoic acid, oxalic acid, adipic acid, sebasic acid, butyric acid, oleic acid, stearic acid, linolic acid, linolenic acid, salicylic acid, benzene sulfonic acid, benzoic acid, p-aminobenzoic acid, p-toluene sulfonic acid, methane sulfonic acid, trifluoromethane sulfonic acid, and trifluoroethane sulfonic acid. The inorganic acid includes, for example, hydrochloric acid, phosphoric acid, nitric acid, boric acid, sulfuric acid, and hydrofluoric acid. They may be used each alone or two or more of them may be used in combination.

The amount of the catalyst used is preferably within a range from 0.0001 to 1 mol based on 1 mol of the compound represented by the general formula (3). When the amount of use is less than 0.0001 mol, the reaction does not tend to proceed substantially and, when it is more than 1 mol, gelation tends to be accelerated during hydrolysis-condensation.

The weight average molecular weight of the thus obtained resin is preferably from 500 to 1,000,000, more preferably from 500 to 500,000, further preferably from 500 to 100,000, particularly preferably from 500 to 10,000, and extremely preferably from 500 to 5,000 with a view point of the solubility to the solvent, the mechanical property, the moldability, etc. When the weight average molecular weight is less than 500, film forming property of the silica based deposition film tends to be deteriorated and, when the weight average molecular weight is more than 1,000,000, compatibility with the solvent tends to be lowered.

### (Ingredient (b))

The solubility inhibitory compound as the ingredient (b) in the invention having the functional group that can be decomposed by the action of the acid and increases the solubility to the alkaline developer by the action of the acid is a compound of a structure in which the functional group that has the dissolution acceleration property to the alkaline developer is protected by a functional group that inhibits dissolution to the alkaline developer (dissolution inhibitory group) and it is contained as an essential ingredient for providing a positive type photosensitivity.

The functional group in the dissolution inhibitory compound that has the dissolution acceleration property to the alkaline developer and constitutes a functional group that can be decomposed by the action of the acid includes a phenolic hydroxyl group or a carboxyl group. Among them, the carboxyl group is preferred since the contrast of the dissolution rate between an exposed region and a not-exposed region can be increased easily.

Further, as the functional group that has the dissolution acceleration property to the alkaline developer, a functional group showing a weakly acidic property is desired and, more specifically, the functional group has a negative common logarithm for an acid dissociation constant pKa preferably of about 2 to 13, and more preferably 3 to 11 as defined by the following general formula (6) which is an index for quantitatively representing the acid strength, and a phenolic hydroxyl group and a carboxyl group belong to such functional group.

pKa=−log [[H⁺][D⁻]/[HD]] (6)

in which Ka represents an acid dissociation constant, HD represents an acid, H⁺ represents a proton formed from the acid HD by dissociation, D⁻ represents an anion formed from the acid HD by dissociation (also referred to as an anion), respectively.

Further, details for the ingredient (b) are to be described. For the ingredient (b), compounds having the following functional groups (b-1) and (b-2) are used.

(b-1)

A phenolic hydroxyl group protected by a dissolution inhibitory group (compound having the general formula (7)):

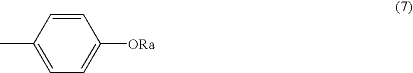

(in which Ra represents a dissolution inhibitory group, which is a functional group selected from methoxymethyl group, benzoyloxymethyl group, methoxyethoxymethyl group, 2-(trimethyl silyl)ethoxymethyl group, methylthiomethyl group, tetrahydropyranyl group, 1-ethoxyethyl group, phenacyl group, cyclopropyl group, isopropyl group, cyclohexyl group, t-butyl group, trimethyl silyl group, t-butyl dimethylsilyl group, t-butyl diphenyl silyl group, triisopropyl silyl group, methyl carbonate group, 1-adamantyl carbonate group, t-butyl carbonate group (t-BOC group), and allylvinyl carbonate group.

Since the phenolic hydroxyl group has a pKa value of about 10 and exhibits a weak acidity, it shows a solubility to an alkaline developer. In a state protected by the dissolution inhibitory group, the solubility to the alkaline developer is lowered relatively compared with a not protected state, and a positive type image can be formed by using the dissolution inhibitory group that can be decomposed by the acid.

(b-2)

A compound having a carboxyl group protected by a dissolution inhibitory group (general formula (8)).

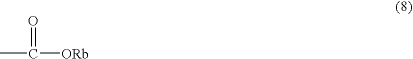

in which Rb represents a dissolution inhibitory group which is a functional group selected from tetrahydropyranyl group, tetrahydrofuranyl group, methoxyethoxymethyl group, benzoyl oxymethyl group, t-butyl group, dicyclopropylmethyl group, 2,4-dimethyl 3-pentyl group, cyclopentyl group, cyclohexyl group, p-methoxybenzyl group, trimethyl silyl group, triethyl silyl group, t-butyl dimethylsilyl group, t-butyl diphenylsilyl group, triisopropyl silyl group, methyl carbonate group, 1-adamantyl carbonate group, t-butyl carbonate group (t-BOC group), and allylvinyl carbonate group.

Since the carboxyl group has a pKa value of about 3 to 5 and has a weak acidity, it shows a solubility to an alkaline developer. In a state protected by the dissolution inhibitory group, the solubility to the alkaline developer is lowered relatively compared with a not protected state, and a positive type image can be formed by using the dissolution inhibitory group that can be decomposed by the acid.

Further, since the acidity of the carboxyl group is stronger than the acidity of the phenolic group, the carboxyl group has more dissolution acceleration effect than the phenolic group and, accordingly, the dissolution contrast to the liquid developer can be increased easily. Further, while the phenolic group tends to form a colored product such as quinone by a chemical reaction such as oxidation, the carboxyl group less forms a colored product in view of an electronic structure and, accordingly, the transparency of the coating film can be increased easily.

As the ingredient (b-2), a compound in which the functional group that can be decomposed by the action of the acid is represented by the following general formula (41) is also suitable.

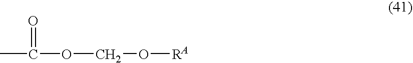

(in the general formula (41), R^{A} represents a functional group selected from substituted or not-substituted linear or branched alkyl groups having 1 to 30 carbon atoms and substituted or not-substituted cycloalkyl groups having 1 to 30 carbon atoms).

The substituted or not-substituted cycloalkyl group having 1 to 30 carbon atoms is represented by the following general formula (42).

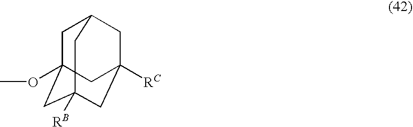

(in the general formula (42), R^{B} and R^{C} are functional groups selected from a hydrogen atom, a hydroxyl group, and alkyl ether groups having 1 to 30 carbon atoms).

Further, the functional group that can be decomposed by the action of the acid in the dissolution inhibitory compound of the ingredient (b) is suitably bonded to the compound represented by general formula (43):

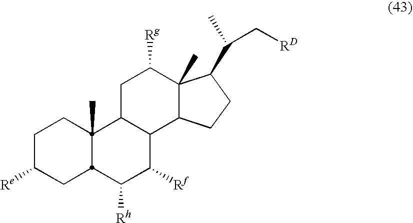

(in the general formula (43), R^{e} is a functional group represented by the general formula (41) that can be decomposed by the action of an acid (in the general formula (41), R^{A} is a functional group selected from substituted or not-substituted linear or branched alkyl groups having 1 to 30 carbon atoms and substituted or not-substituted cycloalkyl groups having 1 to 30 carbon atoms), R^{e}, R^{f}, R^{g}, and R^{e} are functional groups each selected from hydrogen atom, hydroxyl group, alkyl ether groups having 1 to 10 carbon atoms, and an acetoxy ether group).

The functional group that can be decomposed by the action of the acid and represented by the general formula (41) has a structure in which a methylene group connects a carboxyl group and an ether group and, since steric hindrance is low and reactivity with an acid is extremely high, it has an advantage that the spectral sensitivity is high and the resolution is also excellent.

Further, in a case where the group R^{A} bonded to the ether group has a structure shown by the general formula (42), it is advantageous in that the photosensitivity is particularly excellent due to the excellent dissolution inhibitory property of the adamantyl group to the liquid developer. Further, the adamantyl group is also excellent in the heat resistance and the transparency.

Further, in a case where the group to which the functional group that can be decomposed by the action of the acid is bonded has a structure shown by the general formula (43), it is advantageous in view of the dissolution inhibiting property, photosensitivity, transparency, and heat resistance by the effect of the carbon backbone of the general formula (44).

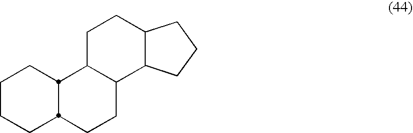

Specific examples of the ingredient (b) used in the invention include the compounds shown in the following drawings.

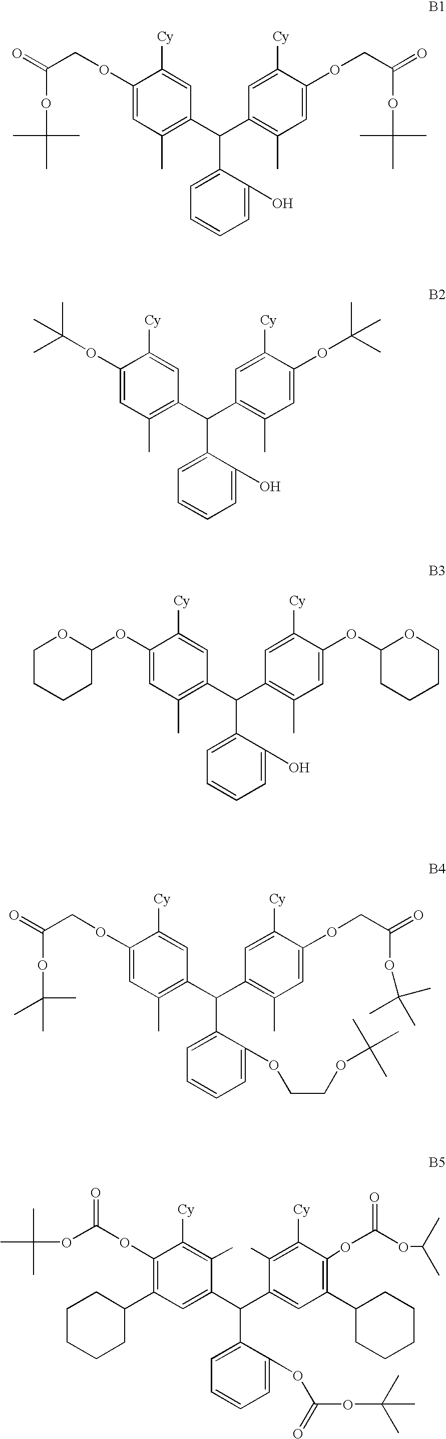

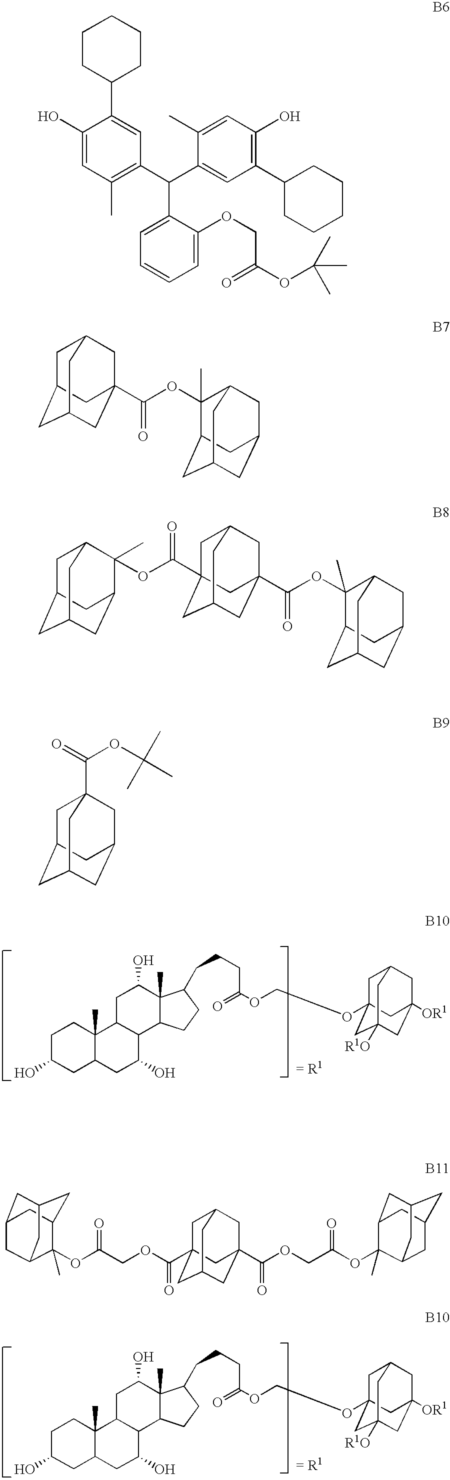

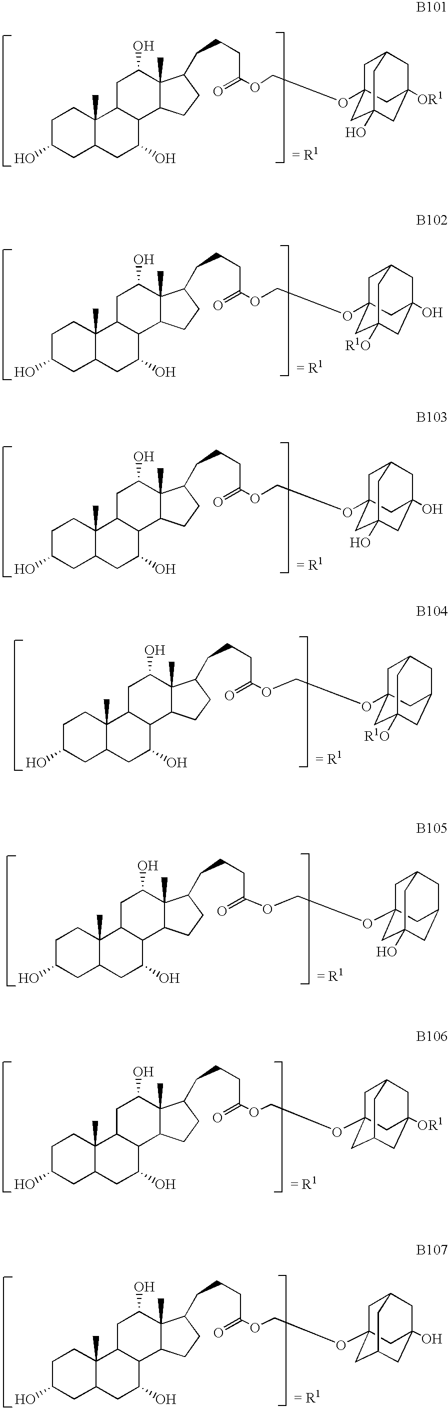

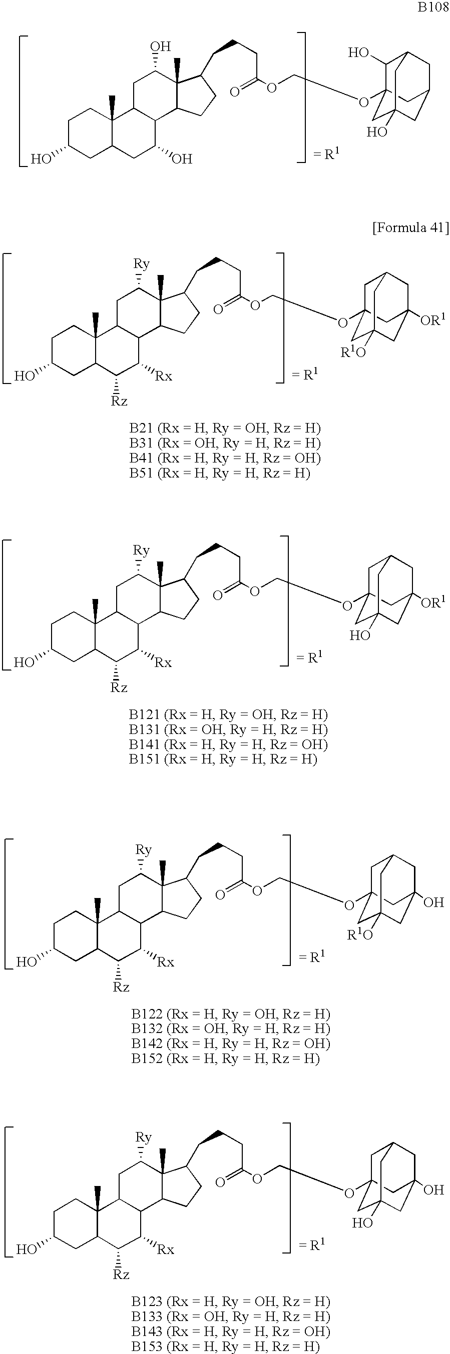

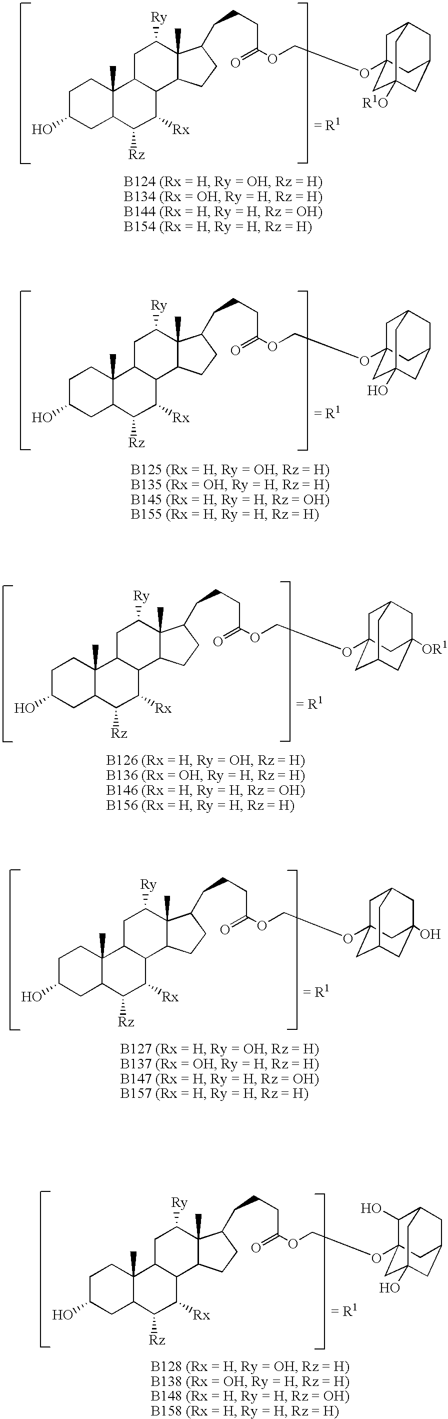

### (Ingredient (c))

As the acid generator (ingredient (c)), any compound can be used so long as the compound generates an acid by the irradiation of a light or an electron beam.

Acid generators include various kinds of generators used so far, for example, onium salt acid generators such as iodonium salts and sulfonium salts, oxime sulfate acid generators, diazomethane acid generators such as bisalkyl or bisallyl sulfonyl diazomethanes and poly(bissulfonyl)diazomethanes, nitrobenzyl sulfonate acid generators, iminosulfonate acid generators, and disulfone acid generators.

The onium acid generator includes, for example, acid generators represented by the following general formula (c-0).

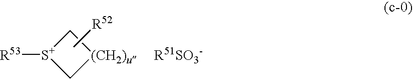

(in which R⁵¹ represents linear, branched, or cycloalkyl groups, or linear, branched or cyclic fluoroalkyl groups; R⁵² represents a hydrogen atom, a hydroxyl group, a halogen atom, linear or branched alkyl groups, linear or branched haloalkyl groups, or linear or branched alkoxy groups; R⁵³ represents allyl groups which may have a substituent; and u″ represents an integer of 1 to 3).

In the general formula (c-0), R⁵¹ represents linear, branched or cycloalkyl groups, or linear, branched or cyclic fluoroalkyl groups. The linear or branched alkyl group has preferably 1 to 10 carbon atoms, more preferably 1 to 8 carbon atoms, and most preferably 1 to 4 carbon atoms.

The cycloalkyl group has preferably 4 to 12 carbon atoms, more preferably 5 to 10 carbon atoms, and most preferably 6 to 10 carbon atoms.

The fluoroalkyl group has preferably 1 to 10 carbon atoms, more preferably 1 to 8 carbon atoms, and most preferably 1 to 4 carbon atoms. Further, fluorination ratio of the fluoroalkyl group (ratio for the number of substituent fluoro atoms based on the number of entire hydrogen atoms in the alkyl group) is preferably from 10 to 100%, and more preferably 50 to 100%. Particularly those in which all hydrogen atoms are substituted by fluorine atoms are preferred since the strength of the acid is increased.

As R⁵¹, the linear alkyl group or the fluoro alkyl group is most preferred.

R⁵² represents a hydrogen atom, a hydroxyl group, a halogen atom, a linear or branched alkyl group, a linear or branched haloalkyl group, or a linear or branched alkoxy group.

In R⁵², the halogen atom includes, for example, fluorine atom, a bromine atom, a chlorine atom, and an iodine atom, and the fluorine atom is preferred.

In R⁵², the alkyl group is linear or branched and the number of carbon atoms thereof is preferably from 1 to 5, particularly preferably from 1 to 4, and further preferably from 1 to 3.

In R⁵², the haloalkyl group is a group in which hydrogen atoms in the alkyl group are partially or entirely substituted by halogen atoms. The alkyl group includes those groups identical with “alkyl group” in R⁵² described above. The substituent halogen atom includes those identical with “halogen atom” described above. In the haloalkyl group, hydrogen atoms are preferably substituted by 50 to 100% based on the entire number of the hydrogen atoms and it is more preferred that all of them are substituted.

In R⁵², the alkoxy group is linear or branched and the number of carbon atoms thereof is preferably from 1 to 5, particularly preferably from 1 to 4, and further preferably from 1 to 3. Among them, the hydrogen atom is preferred for R⁵².

R⁵³ represents an aryl group which may have a substituent. The structure of the basic ring excluding the substituent (ring parent) includes, for example, a naphthyl group, a phenyl group, and an anthracenyl group. The phenyl group is preferred with a view point of the effect of the invention and the absorption of an exposure light such as an ArF excimer laser.

The substituent includes, for example, hydroxyl group and lower alkyl group (linear or branched, in which a preferred number of carbon atoms thereof is 5 or less, and methyl group is particularly preferred).

As the aryl group for R⁵³, those not having the substituent are more preferred. u″ represents an integer of 1 to 3 and it is preferably 2 or 3 and particularly preferably 3.

Preferred acid generator represented by the general formula (c-0) includes the followings.

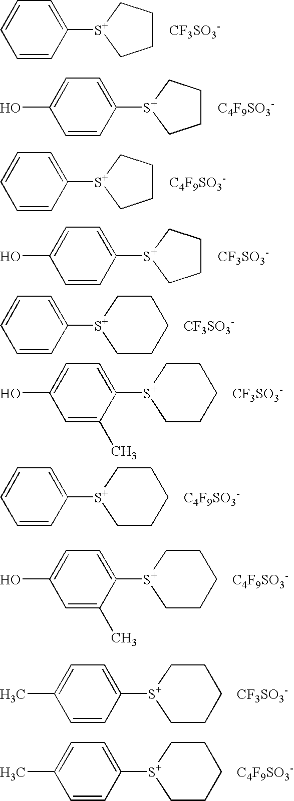

Further, other onium salt acid generators than the acid generators represented by the general formula (c-0) include, for example, those compounds represented by the general formula (c-1) or (c-2).

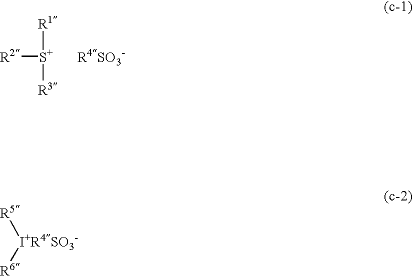

[in which R^{1″} to R^{3″} and R^{5″} to R^{6″} each represent independently an aryl group or an alkyl group respectively; R^{4″} represents a linear, branched or cycloalkyl group, or an fluoroalkyl group; at least one of R^{1″} to R^{3″} represent aryl group and at least one of R^{5″} to R^{6″} represent aryl group].

In the formula (c-1), R^{1″} to R^{3″} each represent independently an aryl group or an alkyl group respectively. Among R^{1″} to R^{3″}, at least one of them represent an aryl group. It is preferred that two or more of R^{1″} to R^{3″} are aryl groups and it is most preferred that all of R^{1″} to R^{3″} are aryl groups.

The aryl group for R^{1″} to R^{3″} is not particularly restricted and, for example, this is an aryl group having 6 to 20 carbon atoms in which the hydrogen atoms of the aryl group may or may not be substituted partially or entirely by an alkyl group, an alkoxyl group, or a halogen atom. For the aryl group, aryl groups having 6 to 10 carbon atoms are preferred since they can be synthesized at a low cost. Specifically, they include, for example, a phenyl group and a naphthyl group.

The alkyl group which may substitute the hydrogen atom of the aryl group is, preferably, an alkyl group having 1 to 5 carbon atoms, and most preferably a methyl group, an ethyl group, a propyl group, an n-butyl group, and a tert-butyl group.

The alkoxy group which may substitute the hydrogen atom of the aryl group includes preferably alkoxy groups having 1 to 5 carbon atoms, and a methoxy group and an ethoxy group are most preferred. The halogen atom which may substitute the hydrogen atom of the aryl group is preferably a fluorine atom.

The alkyl group for R^{1″} to R^{3″} is not particularly restricted and includes, for example, linear, branched, or cycloalkyl groups having 1 to 10 carbon atoms. Those having 1 to 5 carbon atoms are preferred in view of excellent resolution. Specifically, the alkyl group includes, for example, a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decanyl group. The methyl group can be included as a preferred group since it is excellent in the resolution and can be synthesized at a low cost. Among them, each of R^{1″} to R^{3″} is most preferably a phenyl group or a naphthyl group.

R^{4″} represents a linear, branched, or a cyclic alkyl group, or a fluoroalkyl group. The linear or branched alkyl group has preferably 1 to 10 carbon atoms, more preferably 1 to 8 carbon atoms, and most preferably 1 to 4 carbon atoms.

It is preferred that the cycloalkyl group is a cyclic group as shown by R^{1″} and has preferably 4 to 15 carbon atoms, more preferably 4 to 10 carbon atoms, and most preferably 6 to 10 carbon atom.

The fluoroalkyl group has preferably 1 to 10 carbon atoms, more preferably 1 to 8 carbon atoms, and most preferably 1 to 4 carbon atoms. Further, the fluorination ratio of the fluoroalkyl group (ratio of fluorine atoms in the alkyl group) is from 10 to 100%, and more preferably from 50 to 100%, and those in which all hydrogen atoms are substituted by fluorine atoms are preferred since the strength of the acid is increased.

For R^{4″}, a linear or cycloalkyl group or a fluoroalkyl group is most preferred. In the formula (c-2), R^{5″} to R^{6″} each represent independently an aryl group or an alkyl group. At least one of R^{5″} to R^{6″} represents an aryl group. It is preferred that all of R^{5″} to R^{6″} are aryl groups.

The aryl group for R^{5″} to R^{6″} includes those identical with the aryl group for R^{1″} to R^{3″}. The alkyl group for R^{5″} to R^{6″} include those identical with the alkyl group for R^{1″} to R^{3″}. Among them, it is most preferred that all of R^{5″} to R^{6″} are phenyl groups. R^{4″} in the formula (c-2) includes those identical with R^{4″} in the formula (c-1).

Specific examples of the onium salt acid generator represented by the formulae (c-1) and (c-2) include trifluoromethane sulfonate or nonafluorobutane sulfonate of diphenyl iodonium; trifluoromethane sulfonate or nonafluorobutane sulfonate of bis(4-tert-butylphenyl)iodonium; trifluoromethane sulfonate of triphenyl sulfonium, heptafluoropropnae sulfonate thereof, or nonafluorobutahen sulfonate thereof; trifluoromethane sulfonate of tri(4-methylphenyl)sulfonium, heptafluoropropane sulfonate thereof, or nonafluorobutane sulfonate thereof; trifluoromethane sulfonate of dimethyl(4-hydroxynaphthyl)sulfonium, heptafluoropropane sulfonate thereof, or nonafluorobutane sulfonate thereof; trifluoromethane sulfonate of monophenyl dimethyl sulfonium, heptafluoropropane sulfonate thereof, or nonafluorobutane sulfonate thereof; trifluoromethane sulfonate of diphenyl monomethyl sulfonium, heptafluoropropane sulfonate thereof, or nonafluorobutane sulfonate thereof; trifluoromethane sulfonate of (4-methylphenyl)diphenyl sulfonium, heptafluoropropane sulfonate thereof, or nonafluorobutane sulfonate thereof; trifluoromethane sulfonate of (4-methoxyphenyl)diphenyl sulfonium, heptafluoropropane sulfonate thereof, or nonafluorobutane sulfonate thereof; trifluoromethane sulfonate of tri(4-tert-butyl)phenylsulfonium, heptafluoropropane sulfonate thereof; or nonafluorobutane sulfonate thereof; trifluoromethane sulfonate of diphenyl (1-(4-methoxy)naphthyl)sulfonium, heptafluoropropane sulfonate thereof, or nonafluorobutane sulfonate thereof; and trifluoromethane sulfonate of di(1-naphthyl)phenyl sulfonium, heptafluoropropane sulfonate thereof, or nonafluorobutane sulfonate thereof. Further, onium salts in which the anion portion of the onium salt is substituted with methane sulfonate, n-propane sulfonate, n-butane sulfonate, or n-octane sulfonate can also be used.

Further, onium salt acid generators in which the anion portion is replaced with anion portion represented by the following general formula (c-3) or (c-4) in the general formula (c-1) or (c-2) can also be used (cation portion is identical with that in (c-1) or (c-2)).

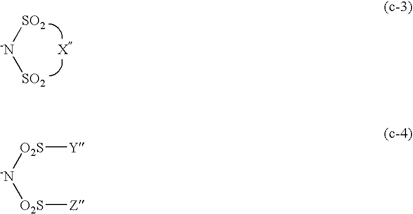

(in which X″ represents alkylene group having 2 to 6 carbon atoms where at least one hydrogen atom is substituted by a fluorine atom; Y″, Z″ each represent independently an alkyl group having 1 to 10 carbon atoms where at least one hydrogen atom is substituted by a fluorine atom).

X″ represents linear or branched alkylene group where at least one hydrogen atom is substituted by fluorine atom, and the alkylene group has 2 to 6 carbon atoms, preferably 3 to 5 carbon atoms, and most preferably 3 carbon atoms.

Y″ and Z″ each represent independently linear or branched alkyl group where at least one hydrogen atom is substituted by a fluorine atom, and the alkyl group has 1 to 10 carbon atoms, preferably 1 to 7 carbon atoms, and more preferably 1 to 3 carbon atoms.

It is more preferred that the number of carbon atoms in the alkylene group X″ and the number of carbon atoms in the alkyl groups Y″, Z″ are smaller by the reason, for example, that also the solubility to the solvent (ingredient (d)) is preferred within the range of the carbon atoms described above.

Further, it is preferred that the number of hydrogen atoms substituted by the fluorine atoms is larger in the alkylene group X″ or in the alkyl groups Y″, Z″, since the acid strength is increased more. The ratio of the fluorine atoms in the alkylene group or the alkyl group, that is, the fluorination ratio is preferably from 70 to 100% and more preferably from 90 to 100%. Most preferred are perfluoroalkylene groups or perfluoroalkyl groups in which all hydrogen atoms are substituted by the fluorine atoms.

In the present specification, the oxime sulfonate acid generator is a compound having at least one group represented by the following general formula (c-5) and having a property of generating an acid by the irradiation of radiation rays. Since such oxime sulfonate acid generators are used generally as chemical amplification type resist compositions, they can be optionally selected and used.

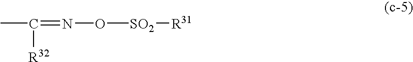

(in the formula (c-5), R³¹ and R³² each represent independently an organic group).

The organic group for R³¹ and R³² is a group containing carbon atoms and may also contain other atoms than the carbon atoms (for example, a hydrogen atom, an oxygen atom, a nitrogen atom, a sulfur atom, a halogen atom (fluorine atom, chlorine atom, etc.)).

As the organic group R³¹, linear, branched or cycloalkyl groups or aryl groups are preferred. The alkyl groups and the aryl groups may also have a substituent. The substituent is not particularly restricted and includes, for example, a fluorine atom, a linear, branched, or cyclic alkyl group having 1 to 6 carbon atoms. “have a substituent” means that hydrogen atoms in the alkyl group or aryl group are partially or entirely substituted by substituents.

For the alkyl group, the number of carbon atoms is preferably from 1 to 20, more preferably from 1 to 10, further preferably from 1 to 8, particularly preferably from 1 to 6, and most preferably from 1 to 4. As the alkyl group, alkyl groups partially or completely halogenated (hereinafter sometimes referred to as a haloalkyl group) are particularly preferred. The partially haloalkyl group means an alkyl group in which hydrogen atoms are partially substituted by halogen atoms, and the completely haloalkyl group means an alkyl group in which hydrogen atoms are entirely substituted by the halogen atoms. The halogen atom includes, for example, a fluorine atom, a chlorine atom, a bromine atom, and an iodine atom. The fluorine atom is particularly preferred. That is, the haloalkyl group is preferably a fluoroalkyl group.

For the aryl group, the number of carbon atoms is, preferably from 4 to 20, more preferably from 4 to 10, and most preferably from 6 to 10. As the alkyl group, partially or completely halogenated aryl groups are particularly preferred. The partially halogenated aryl group means an aryl group in which hydrogen atoms are partially substituted by halogen atoms, and the completely halogenated aryl group means an aryl groups in which hydrogen atoms are entirely substituted by the halogen atoms.

As R³¹, alkyl group having 1 to 4 carbon atoms and not having a substituent, or fluoroalkyl group having 1 to 4 carbon atoms is particularly preferred.

As the organic group for R³², a linear, branched, or cycloalkyl group, aryl group, or cyano group is preferred. The alkyl group or the aryl group for R³² includes the alkyl group or aryl group identical with that referred to for R³¹. As R³², a cyano group, an alkyl group having 1 to 8 carbon atoms not having a substituent, or a fluoroalkyl group having 1 to 8 carbon atoms is preferred.

A further preferred oxime sulfonate acid generator includes the compounds represented by the following general formula (c-6) or (c-7).

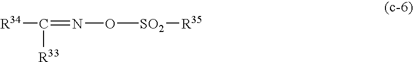

(in the formula (c-6), R³³ represents a cyano group, an alkyl group not having a substituent, or a haloalkyl group. R³⁴ represents an aryl group. R³⁵ represents an alkyl group not having a substituent or a haloalkyl group).

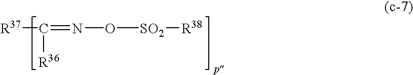

(in the formula (c-7), R³⁶ represents a cyano group, an alkyl group not having a substituent, or a haloalkyl group. R³⁷ represents a bivalent or trivalent aromatic hydrocarbon group. R³⁸ represents an alkyl group not having a substituent or haloalkyl group. p″ represents 2 or 3).

In the general formula (c-6), the alkyl group not having the substituent or the haloalkyl group for R³³ has preferably 1 to 10 carbon atoms, more preferably 1 to 8 carbon atoms, and most preferably 1 to 6 carbon atoms.

The aryl group for R³⁴ includes, for example, groups formed by removing one hydrogen atom from the ring of an aromatic hydrocarbon, for example, a phenyl group, a biphenyl group, a fluorenyl group, a naphthyl group, an anthracyl group, and a phenanthryl group, and heteroaryl groups formed by substituting a portion of the carbon atoms constituting the rings of such aromatic groups by hetero-atoms such as an oxygen atom, a sulfur atom, and a nitrogen atom. Among then, the fluorenyl group is preferred.

The aryl group for R³⁴ may have a substituent such as an alkyl group, a haloalkyl group, or an alkoxy group having 1 to 10 carbon atoms. In the alkyl group or the haloalkyl group of the substituent, the number of carbon atoms is preferably from 1 to 8 and more preferably from 1 to 4. Further, the haloalkyl group is preferably a fluoroalkyl group.

The alkyl group not having the substituent or the haloalkyl group of R³⁵ has a number of carbon atoms preferably from 1 to 10, more preferably from 1 to 8, and most preferably from 1 to 6.

In the general formula (c-7), the alkyl group not having the substituent or the halogenated haloalkyl group of R³⁶ includes those identical with the alkyl group not having the substituent or the haloalkyl group of R³³.

The bivalent or trivalent aromatic hydrocarbon group of R³⁷ include those groups in which one or more hydrogen atoms is removed further from the aryl group of R³⁴.

The alkyl group not having the substituent or the haloalkyl group of R³⁸ includes those identical with the alkyl group not having the substituent or the haloalkyl group of R^{3s}. p″ is preferably 2.

Specific examples of the oxime sulfonate acid generator include, for example, α-(p-toluene sulfonyloxyimino)-benzylcyanide, α-(p-chlorobenzene sulfonyloxyimino)-benzylcyanide, α-(4-nitrobenzene sulfonyloxyimino)-benzylcyanide, α-(4-nitro-2-trifluoromethylbenzene sulfonyloxyimino)-benzylcyanide, α-(benzenesulfonyloxyimino)-4-chlorobenzylcyanide, α-(benzenesulfonyloxyimino)-2-4-dichlorobenzylcyanide, α-(benzenesulfonyloxyimino)-2,6-dichlorobenzylcyanide, α-(benzenesulfonyloxyimino)-4-methoxybenzylcyanide, α-(2-chlorobenzene sulfonyloxyimino)-4-methoxybenzylcyanide, α-(benzenesulfonyloxyimino)-thiene-2-ylacetonitrile, α-(4-dodecylbenzenesulfonyloxyimino)-benzylcyanide, α-[(p-toluene sulfonyloxyimino)-4-methoxyphenyl]acetonitrile, α-[(dodecylbenzene sulfonyloxyimino)-4-methoxyphenyl]acetonitrile, α-(tosyloxyimino)-4-thienylcyanide, α-(methylsulfonyloxyimino)-1-cyclopenthenylacetonitrile, α-(methylsulfonyloxyimino)-1-cyclohexanylacetonitrile, α-(methylsulfonyloxyimino)-1-cycloheptenylacetonitrile, α-(methylsulfonyloxyimino)-1-cyclooctenylacetonitrile, α-(trifluoromethyl sulfonyloxyimino)-1-cyclopentenylacetonitrile, α-(trifluoromethyl sulfonyloxyimino)-cyclohexylacetonitrile, α-(ethylsulfonyloxyimino)-ethylacetonitrile, α-(propylsulfonyloxyimino)-propylacetonitrile, α-(cyclohexylsulfonyloxyimino)-cyclopentylacetonitrile, α-(cyclohexylsulfonyloxyimino)-cyclohexylacetonitrile, α-(cyclohexylsulfonyloxyimino)-1-cyclopentenylacetonitrile, α-(ethylsulfonyloxyimino)-1-cyclopentenylacetonitrile, α-(isopropylsulfonyloxyimino)-1-cyclopentenylacetonitrile, α-(n-butylsulfonyloxyimino)-1-cyclopentanyl acetonitrile, α-(ethylsulfonyloxyimino)-1-cyclohexenyl acetonitrile, α-(isopropyl sulfonyloxyimino)-1-cyclohexenyl acetonitrile, α-(n-butyl sulfonyloxyimino)-1-cyclohexenyl acetonitrile, α-(methylsulfonyloxyimino)-phenylacetonitrile, α-(methylsulfonyloxyimino)-p-methoxyphenylacetonitrile, α-(trifluoromethyl sulfonyloxyimino)-phenylacetonitrile, α-(trifluoromethyl sulfonyloxyimino)-p-methoxyphenyl acetonitrile, α-(ethylsulfonyloxyimino)-p-methoxyphenylacetonitrile, α-(propylsulfonyloxyimino)-p-methylphenyl acetonitrile, and α-(methylsulfonyloxyimino)-p-bromophenyl acetonitrile.

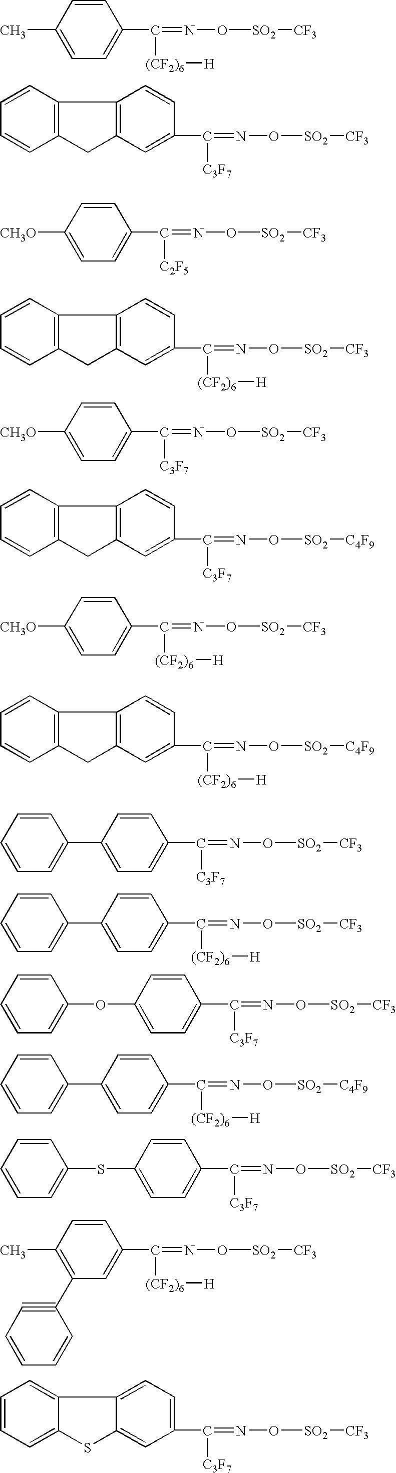

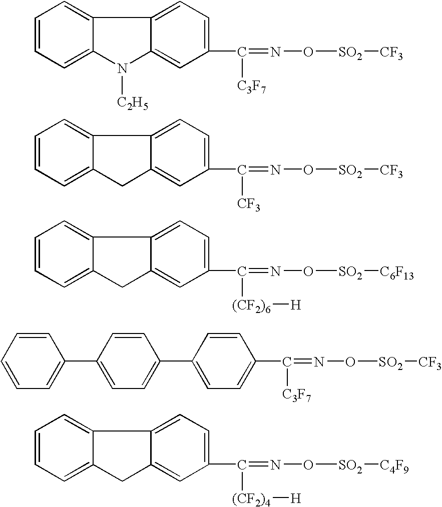

A triazine acid generators shown below can also be used suitably.

An oxazole derivative represented by the following general formula (PAG1), or an S-triazine-derivative represented by the following general formula (PAG2) substituted by a trihalomethyl group.

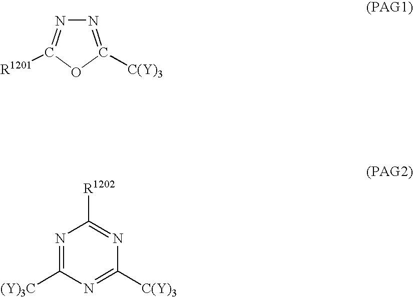

in the formula, R¹²⁰¹ represents a substituted or not-substituted aryl group or an alkenyl group, and R¹²⁰² represents a substituted or not-substituted aryl group, an alkenyl group, an alkyl group or —C(Y)₃. Y represents a chlorine atom or a bromine atom.

Specifically, the following compounds can be included but they are not limitative.

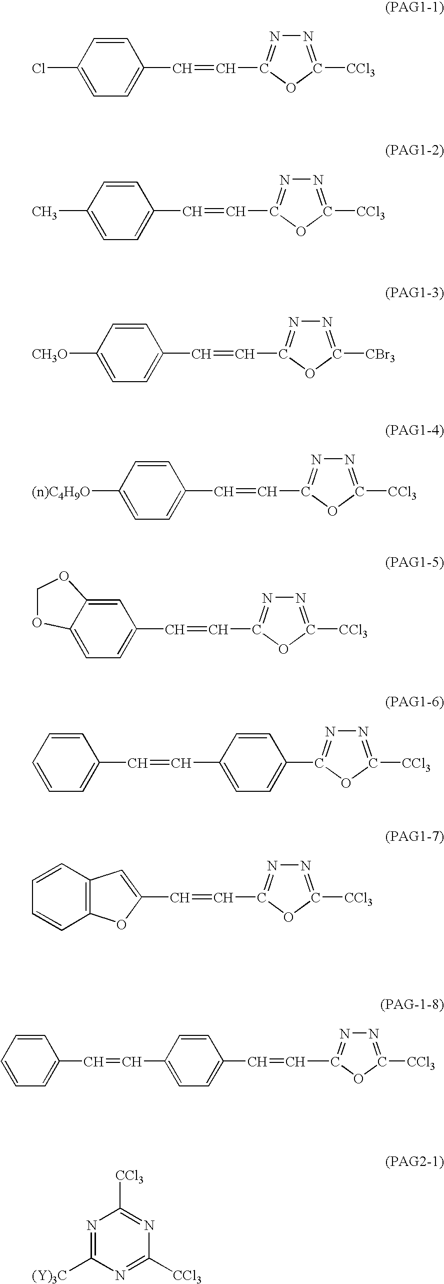

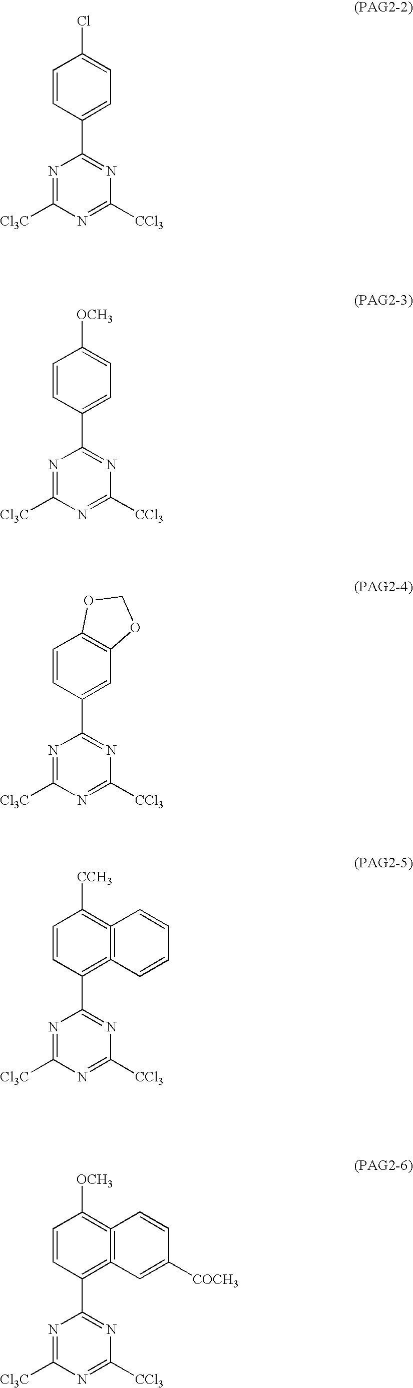

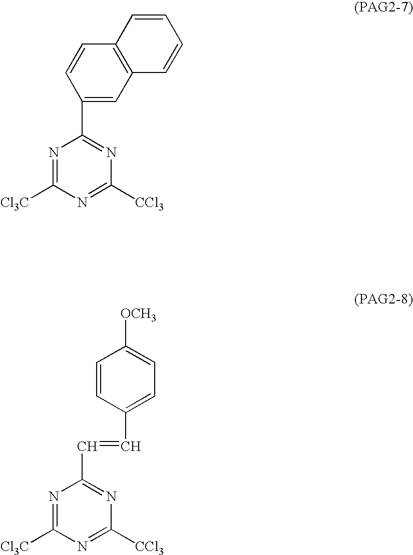

An acid generator of a disulfonic derivative represented by the following general formula (PAG5) or an imino sulfonate derivative represented by the following general formula (PAG6) can also be used suitably.

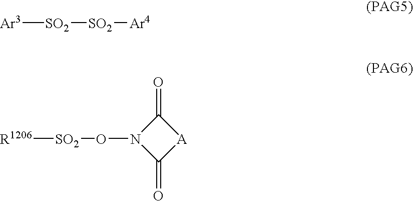

In the formula, Ar³ and Ar⁴ each represent independently a substituted or not-substituted aryl group. R¹²⁰⁶ represents a substituted or not-substituted alkyl group or an aryl group. A represents a substituted or not-substituted alkylene group, an alkenylene group, or an arylene group. Specific examples include the compounds shown below but they are not limitative.

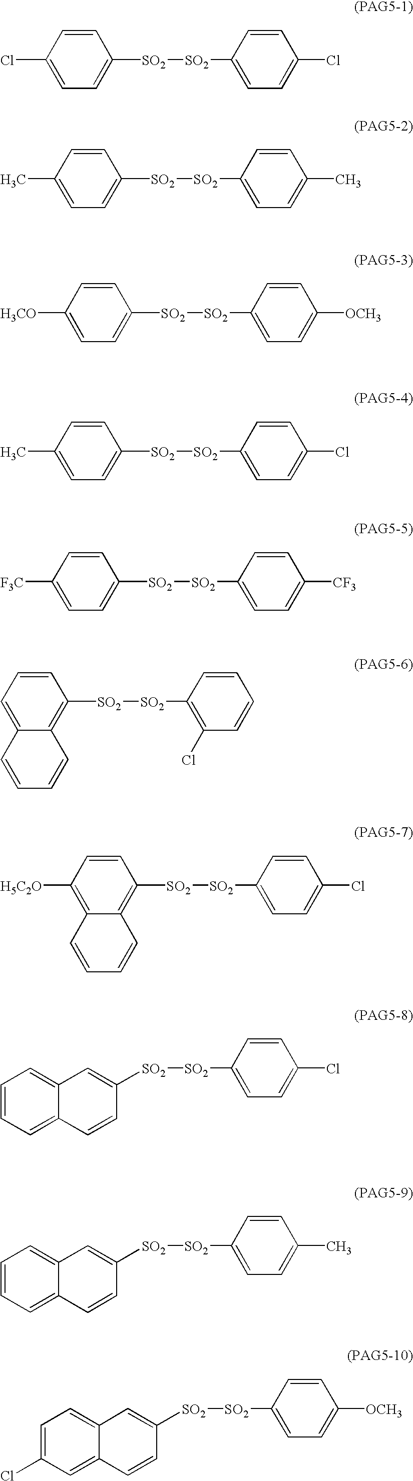

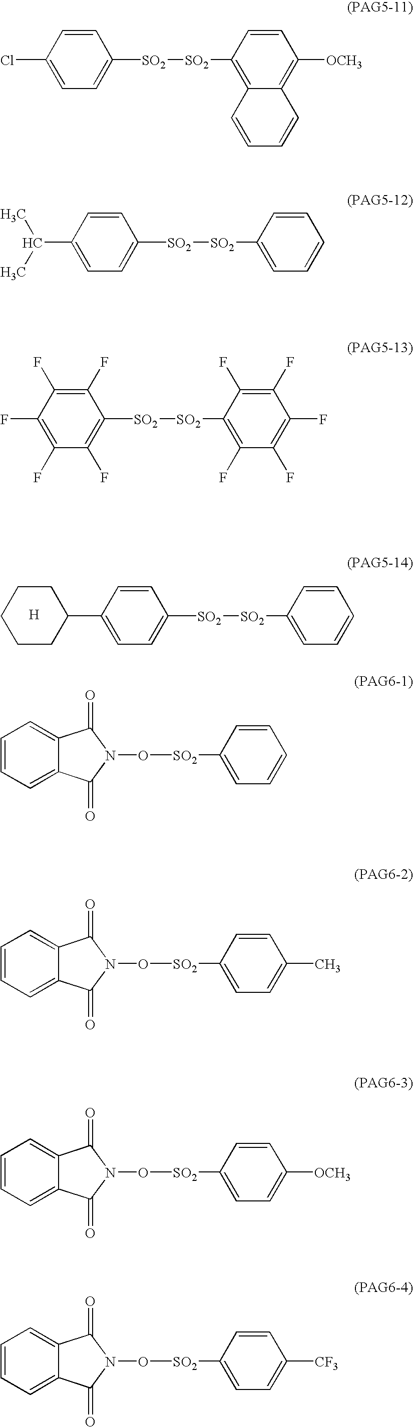

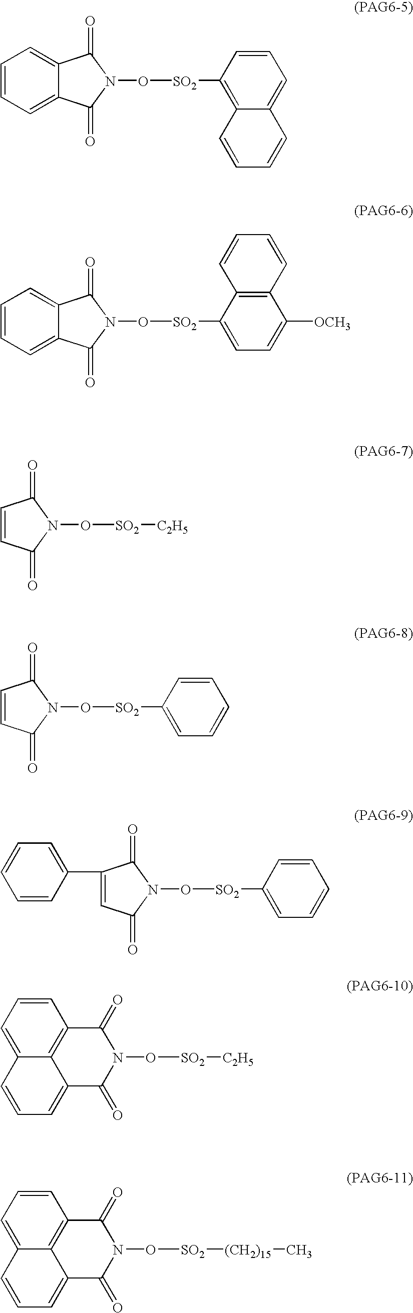

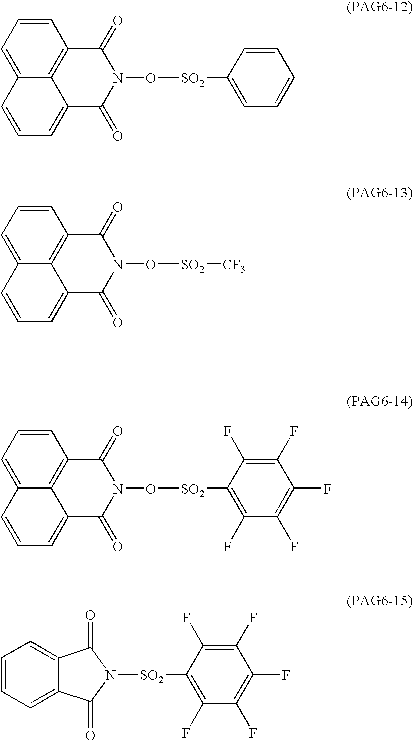

Among the acid generators listed above, the triazine acid generators and the iminosulfonate acid generators are preferred with a view point of the efficiency of generating an acid and the strength of the acid. Further, both type of the acid generators are preferred also in a case of use under exposure of long wave UV-rays such as i-line (wavelength: 365 nm), g-line (wavelength: 436 nm), and h-line (wavelength: 405 nm), or visible light.

### (Ingredient (d))

As the solvent capable of dissolving the ingredient (a) includes, for example, aprotic solvents and protic solvents. They can be used each alone or two or more of them are used in combination.

The aprotic solvent includes, for example, ketone solvents such as acetone, methyl ethyl ketone, methyl-n-propyl ketone, methyl-iso-propyl ketone, methyl-n-butyl ketone, methyl-iso-butyl ketone, methyl-n-pentyl ketone, methyl-n-hexyl ketone, diethyl ketone, dipropyl ketone, di-iso-butyl ketone, trimethylnonanone, cyclohexanone, cyclopentanone, methylcyclohexanone, 2,4-pentanedione, acetonylacetone, γ-butyrolactone, and γ-valerolactone; ether solvents such as diethyl ether, methyl ethyl ether, methyl-n-di-n-propyl ether, di-iso-propyl ether, tetrahydrofuran, methyltetrahydrofuran, dioxane, dimethyl dioxane, ethylene glycol dimethyl ether, ethylene glycol diethyl ether, ethylene glycol di-n-propyl ether, ethylene glycol dibutyl ether, diethylene glycol dimethyl ether, diethylene glycol diethyl ether, diethylene glycol methyl ethyl ether, diethylene glycol methyl mono-n-propyl ether, diethylene glycol methyl mono-n-butyl ether, diethylene glycol di-n-propyl ether, diethylene glycol di-n-butyl ether, diethylene glycol methyl mono-n-hexyl ether, triethylene glycol dimethyl ether, triethylene glycol diethyl ether, triethylene glycol methylethyl ether, triethylene glycol methyl mono-n-butyl ether, triethylene glycol di-n-butyl ether, triethylene glycol methyl mono-n-hexyl ether, tetraethylene glycol dimethyl ether, tetraethylene glycol diethyl ether, tetradiethylene glycol methylethyl ether, tetraethylene glycol methyl mono-n-butyl ether, diethylene glycol di-n-butyl ether, tetraethylene glycol methyl mono-n-hexyl ether, tetraethylene glycol di-n-butyl ether, propylene glycol dimethyl ether, propylene glycol diethyl ether, propylene glycol di-n-propyl ether, propylene glycol dibutyl ether, dipropylene glycol dimethyl ether, dipropylene glycol diethyl ether, dipropylene glycol methylethyl ether, dipropylene glycol methyl mono-n-butyl ether, dipropylene glycol di-n-propyl ether, dipropylene glycol di-n-butyl ether, dipropylene glycol methyl mono-n-hexyl ether, tripropylene glycol dimethyl ether, tripropylene glycol diethyl ether, tripropylene glycol methylethyl ether, tripropylene glycol methyl mono-n-butyl ether, tripropylene glycol di-n-butyl ether, tripropylene glycol methyl mono-n-hexyl ether, tetrapropylene glycol dimethyl ether, tetrapropylene glycol diethyl ether, tetradipropylene glycol methylethyl ether, tetrapropylene glycol methyl mono-n-butyl ether, dipropylene glycol di-n-butyl ether, tetrapropylene glycol methyl mono-n-hexyl ether, and tetrapropylene glycol di-n-butyl ether; ester solvents such as methyl acetate, ethyl acetate, n-propyl acetate, i-propyl acetate, n-butyl acetate, i-butyl acetate, sec-butyl acetate, n-pentyl acetate, sec-pentyl acetate, 3-methoxybutyl acetate, methyl pentyl acetate, 2-ethylbutyl acetate, 2-ethylhexyl acetate, benzyl acetate, cyclohexyl acetate, methylcyclohexyl acetate, nonyl acetate, methyl acetoacetate, ethyl acetoacetate, diethylene glycol monomethyl ether acetate, diethylene glycol monoethyl ether acetate, diethylene glycol mono-n-butyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, and di-n-oxalate; ether acetate solvents such as ethylene glycol methyl ether propionate, ethylene glycol ethyl ether propionate, ethylene glycol methyl ether acetate, ethylene glycol ethyl ether acetate, diethylene glycol methyl ether acetate, diethylene glycol ethyl ether acetate, diethylene glycol n-butyl ether acetate, propylene glycol methyl ether acetate, propylene glycol ethyl ether acetate, propylene glycol propyl ether acetate, dipropylene glycol methyl ether acetate, and dipropylene glycol ethyl ether acetate; acetonitrile, N-methyl pyrrolidinone, N-ethyl pyrrolidinone, N-propyl pyrrolidinone, N-butyl pyrrolidinone, N-hexyl pyrrolidinone, N-cyclohexyl pyrrolidinone, N,N-dimethyl formamide, N,N-dimethylacetoamide, and N,N-dimethyl sulfoxide. With a view point of increasing the film thickness and the solution stability, the ether solvents, ether acetate solvents and ketone solvents are preferred.

Among them, with the inventors' view point of suppressing coating unevenness or repellency, the ether acetate solvent is most preferred and the ether solvent is preferred in the second place, and the ketone solvent is preferred in the third place. The solvents may be used each alone or two or more them may be used in combination.

The protonic solvent includes, for example, alcohol solvents such as methanol, ethanol, n-propanol, i-propanol, n-butanol, i-butanol, sec-butanol, t-butanol, n-pentanol, i-pentanol, 2-methyl butanol, sec-pentanol, t-pentanol, 3-methoxybutanol, n-hexanol, 2-methylpentanol, sec-hexanol, 2-ethyl butanol, sec-heptanol, n-octanol, 2-ethyl hexanol, sec-octanol, n-nonyl alcohol, n-decanol, sec-undecyl alcohol, trimethyl nonyl alcohol, sec-tetradecyl alcohol, sec-heptadecyl alcohol, phenol, cyclohexanol, methyl cyclohexanol, benzyl alcohol, ethylene glycol, 1,2-propylene glycol, 1,3-butylene glycol, diethylene glycol, dipropylene glycol, triethylene glycol, and tripropylene glycol; ether solvents such as ethylene glycol methyl ether, ethylene glycol ethyl ether, ethylene glycol monophenyl ether, diethylene glycol monomethyl ether, diethylene glycol monoethyl ether, diethylene glycol mono-n-butyl ether, diethylene glycol mono-n-hexyl ether, ethoxytriglycol, tetraethylene glycol mono-n-butyl ether, propylene glycol monomethyl ether, dipropylene glycol monomethyl ether, dipropylene glycol monoethyl ether, and tripropylene glycol monomethyl ether; and ester solvents such as methyl lactate, ethyl lactate, n-butyl lactate, and n-amyl lactate. With a view point of the storage stability, the alcohol solvents is preferred.

With the inventors' view point of suppressing the coating unevenness or water repellency, ethanol, isopropyl alcohol, propylene glycol propyl ether, etc. are preferred. They may be used each alone or two or more of them may be used in combination.

The method of using the ingredient (b) and the ingredient (c) is not particularly limited and includes, for example, a method of using as a solvent upon preparing the ingredient (a), a method of adding the same after preparation of the ingredient (a), a method of solvent exchange, or a method of taking out the ingredient (a) by solvent distillation, etc. and adding the solvent (b).

Further, the silica type deposition film forming the composition of the invention may optionally contain water but it is preferably within a range not deteriorating the aimed property. Further, the dissolution inhibitory compound of the ingredient (b) and the photo acid generator of the ingredient (c) are used being dissolved together with the siloxane resin of the ingredient (a) in the solvent of the ingredient (d).

The addition amount of the ingredient (b) is preferably from 3% to 30%, more preferably from 5% to 25%, and further preferably from 5% to 20% by weight ratio in the composition based on the entire solid of the siloxane resin. The dissolution inhibitory compound having the dissolution inhibitory group of the ingredient (b) originally shows no solubility to the alkaline developer and inhibits dissolution of the siloxane resin to the alkaline developer. However, an acid is generated from the photo acid generator of the ingredient (c) by the irradiation of UV-ray or visible light, the acid catalyst reaction is taken place between the generated acid and the dissolution inhibitory compound of the ingredient (b) during the heating step succeeding to the irradiation of the UV-ray or visible light to induce the decomposition of the dissolution inhibitory group and the dissolution inhibitory compound is transformed to the dissolution accelerating compound, by which the compound shows high solubility to the alkaline developer.

When the addition amount of the ingredient (b) is less than 5%, since the dissolution inhibitory property to the not exposed region is lowered, the not exposed region is dissolved and no sufficient photosensitivity can sometimes be obtained.

Further, when the addition amount of the ingredient (b) is more than 30%, this tends to result precipitation in the coating film making it not uniform, or lower the transparency, electric property, or mechanical strength of the dielectric film obtained by heat curing the coating film.

The photo acid generator of the ingredient (c) is preferably from 0.1% to 20%, more preferably from 0.5% to 15%, and further preferably from 1% to 10% in the composition based on the weight of the siloxane resin of the ingredient (a). When the addition amount of the ingredient (c) is more than 20%, this tends to result precipitation in the coating film making it not uniform, deterioration of the photosensitivity, and lowering of the transparency, electric property, or mechanical strength of the dielectric film obtained by heat curing the coating film. Further, when the addition amount of the ingredient (c) is less than 1%, the amount of the acid generated by exposure becomes insufficient to sometimes cause lowering of the sensitivity or failure of forming a positive pattern.

When the silica based positive type photosensitive resin composition of the invention is used for electronic parts, etc., it is preferred that an alkali metal or an alkaline earth metal is not contained and the concentration of metal ions thereof, if contained in the composition, is preferably 1,000 ppm or less and 1 ppm or less.

When the concentration of the metal ions is more than 1,000 ppm, metal ions tend to flow into an electronic part having a silica based deposition film obtained from the composition to possibly give undesired effects on the electric performance per se. Accordingly, it is effective to remove the alkali metal or alkaline earth metal from the composition, for example, by using an ion exchange filter or the like. However, this is not always necessary in the use for an optical waveguide channel or like other application use unless the purpose thereof is impaired.

A method of forming a silica based deposition film over a substrate by using the silica type photosensitive resin composition of the invention described above is to be explained for an example of a spin coating method which is generally excellent in the film deposition property and the film uniformity. However, the method of forming the silica based deposition film is not limited to the spin coating method but various kinds of methods such as a spraying method, a roll coating method, a spin-coating method or a slit coating method can be utilized.

Further, the substrate may have a planer surface or an uneven surface with formation of an electrode or the like. For the substrate, organic polymers such as polyethylene terephthalate, polyethylene naphthalate, polyamide, polycarbonate, polyacryl material, nylon, polyether sulfone, polyvinyl chloride, polypropylene, and triacetyl cellulose may also be used in addition to those described above. Further, plastic films such as made of the organic polymers described above can also be used.

At first, a silica based positive type photosensitive resin composition is spin coated over a substrate such as a silicon wafer or a glass substrate preferably at 300 to 3,000 rpm, and more preferably at 400 to 2,000 rpm to form a deposition film. When the number of rotation is less than 300 rpm, the film uniformity tends to be worsened and when it is more than 3,000 rpm, the film depositability may possibly be worsened.

The thickness of the silica based deposition film is different depending on the application use and the thickness is preferably from 0.01 to 2 μm when used as an interlayer dielectric for LSI, etc. and preferably from 2 to 40 μm when used as a passivation layer. When it is used for a liquid crystal application, the thickness is preferably from 0.1 to 20 μm. When it is used as a photoresist, the thickness is preferably from 0.1 to 2 μm, and when it is used for an optical waveguide channel the thickness is preferably from 1 to 50 μm.

Usually, the film thickness is preferably about from 0.01 to 10 μm, more preferably from 0.01 to 5 μm, further preferably from 0.01 to 3 μm, particularly preferably from 0.05 to 3 μm, and extremely preferably, from 0.1 to 3 μm. The silica based positive type photosensitive resin composition of the invention can be used at a thickness of preferably from 0.5 to 3.0 μm, more preferably from 0.5 to 2.5 μm, and particularly preferably from 1.0 to 2.5 μm.

For controlling the thickness of the silica based deposition film, the concentration of the ingredient (a) in the composition may be controlled for instance. Further, when the spin coating method is used, the thickness can be controlled by controlling the number of rotation and the number of coating times. In a case of controlling the thickness by controlling the concentration of the ingredient (a), this can be controlled by increasing the concentration of the ingredient (a) when the film is intended to be thick and by decreasing the concentration of the ingredient (a) when the film is intended to be thin.

In a case of controlling the film thickness by using the spin coating method, it can be controlled, for example, by decreasing the number of rotation or increasing the number of coating times when the film is intended to be thick, or by increasing the number of rotation or decreasing the number of rotation times when the film is intended to be thin.

Then, the organic solvent in the coating film is dried by a hot plate or the like at a temperature preferably of from 50 to 200° C. and more preferably from 80 to 180° C. When the drying temperature is lower than 50° C., the organic solvent is not tended to be dried sufficiently. When the prebaking temperature is higher than 200° C., since curing of the deposition film proceeds and solubility to the developer is lowered, this may sometimes lower the exposure sensitivity or lower the resolution.

Then, a light or an electron beam is irradiated to the formed coating film by way of a predetermined mask. The light or the electron beam used herein includes, for example, UV-ray such as g-line (wavelength: 436 nm) and an i-line (wavelength: 365 nm), far UV-ray such as KrF excimer laser, X-ray such as a synchrotron radiation ray, and charged particle-ray such as an electron beam. Among them, g-line and i-line are preferred. The exposure amount is usually from 1 to 2,000 mJ/cm² and preferably from 10 to 200 mJ/cm².

After irradiating the light or the electron beam, a desired pattern can be obtained by applying a developing treatment using a developer to remove a portion irradiated by the light or the electron beam. The developer that can be used preferably herein includes aqueous alkaline solutions formed by dissolving, in water, inorganic alkalis such as sodium hydroxide, potassium hydroxide, sodium carbonate, sodium silicate, and aqueous ammonia, primary amines such as ethylamine and n-propylamine, secondary amines such as diethyl amine and di-n-propylamine, tertiary amines such as triethyl amine and methyl diethyl amine, alcohol amines such as dimethyl ethanol amine, and triethanol amine; quaternary ammonium salts such as tetramethyl ammonium hydroxide, tetraethyl ammonium hydroxide, and choline, and cyclic amines such as pyrrole, piperidine, 1,8-diazabicyclo-(5,4,0)-7-undecene, and 1,5-diazabicyclo-(4,3,0)-5-nonane.

Further, the developer can be used also with addition of a water soluble organic solution, for example, alcohols such as methanol and ethanol, or a surfactant each in an appropriate amount. Further, various kinds of organic solvents that dissolve the composition of the invention can also be used as the developer.

For the developing method, an appropriate method such as a liquid deposition method, a dipping method, or an immersion-shaking method can be utilized. After the developing treatment, a rinsing treatment, for example, by using running water cleaning may be applied to the patterned film.

It is effective to control the composition, process conditions and exposure conditions such that the dissolving rate of the silica based coating film to the developer is optimized for patterning. Further, it is also effective to control the concentration, the composition, etc. of the developer. For the not-exposed region of the silica based coating film, the dissolving rate to the developer to be used is from 0 to 20 nm/s, preferably from 0 to 10 nm nm/s, and further preferably from 0 to 5 nm/s.

When the dissolving rate for the not-exposed region of the silica based coating film is higher than 10 nm/s, the coating film thickness decreases in the developing step to result disadvantages that no desired film thickness can be obtained after development, the resolution is insufficient, the efficiency of utilizing the material is lowered, etc. On the other hand, the dissolving rate of the exposed region to the developer is from 20 to 10,000 nm/s, preferably from 30 to 1,000 nm/s, and further preferably from 40 to 200 nm/s. The dissolution rate is preferably optimized such that a preferred dissolving rate is obtained both for the not-exposed region and the exposed region.

For decomposing the photo acid generator present in the remaining film after the development, the film may sometimes be exposed for the entire surface. As an exposure light source, the light source identical with that used for the patterning can be used. Since it is necessary to decompose the photo acid generator completely, the exposure amount is usually from 100 to 3,000 mJ/cm², and preferably from 200 to 2,000 mJ/cm². The step may not be applied depending on the case.

Then, the patterned deposition film is baked at a heating temperature of 250 to 500° C. for final curing, and a pattered silica based deposition film is formed. The final curing is preferably performed in an inert atmosphere such as nitrogen, argon or helium. In this case, the oxygen concentration is preferably 1,000 ppm or less. When the heating temperature is lower than 250° C., sufficient curing is not tended to be attained and, when it is higher than 500° C., the amount of heat input increases to possibly degrade a metal wiring when a metal wiring layer is present. Accordingly, it is preferred to perform final curing at a temperature of 450° C. or lower.

The heating temperature upon curing is from 2 to 60 min and preferably from 2 to 30 min. When the heating time is longer than 60 min, the amount of heat input increases excessively to possibly degrade the wiring metal. As the heating apparatus, heat treatment apparatus such as a quartz tube furnace or like other furnace, a hot plate, a rapid thermal annealing system (RTA), or a heat treatment apparatus using EB or UV together is used preferably.

The interlayer dielectric of the liquid crystal display device of the invention formed as described above has sufficiently high heat resistance and high transparency and is also excellent in the solvent resistance, even when a heating treatment is performed at 350° C. The upper limit of the heat resistance temperature is about 230° C. for interlayer dielectrics formed of a composition containing a phenolic resin such as a novolac resin and a quinone diazide photosensitive agent material, or a composition containing an acrylic resin and a quinone diazide photosensitive agent material and, when a heating treatment is performance at a temperature higher than the upper limit, the interlayer dielectric is colored yellow or brown and the transparency is remarkably deteriorated.

The silica based deposition film formed as described above can be used as an interlayer dielectric for liquid crystal display devices, plasma displays, or organic EL, field emission displays and semiconductor devices. Further, the film can be used, for example, as wafer coat materials (surface protection film, bump protecting film, MCM (multi-chip module) interlayer protection film, junction coat), packaging material (sealant, die bonding material) for semiconductor devices.

### Embodiment 1

The present invention is to be described by way of specific examples but the invention is not limited to them.

### (Synthesis of Siloxane Resin Soluble to Aqueous Alkaline Solution)

### Resin A:

### Synthesis of 3-acetoxypropyl Silsesquioxane/Phenyl Silsesquioxane/Methyl Silsesquioxane Copolymer

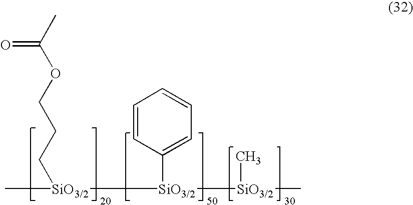

(20:50:30 in the structural formula represents a molar ratio of starting materials used)

Into a 500 mL four-necked flask equipped with a stirrer, a reflux condenser, a dropping funnel, and a thermometer, 55.8 g of toluene, and 35.7 g of water were charged, and 3.12 g (0.03 mol) of 35% hydrochloric acid was added. Then, a solution of 13.5 g (0.0605 mol) of 3-acetoxypropyl trimethoxysilane, 30.0 g (0.151 mol) of phenyl trimethoxy silane, and 12.4 g (0.0908 mol) of methyl trimethoxysilane in 27.9 g of toluene was dropped at 20 to 30° C.

After the dropping was completed, they were aged at the identical temperature for 2 hr. As a result of GC analysis for the reaction solution, it was found that the starting materials were not left. Then, after extraction with addition of toluene and water, the extracts were cleaned with an aqueous solution of sodium hydrogen carbonate and then cleaned with water till the solution became neutral. A toluene oil layer was recovered, and toluene was removed to obtain 34.6 g of an aimed viscous liquid compound. Further, it was dissolved in propylene glycol monomethyl ether acetate to obtain a solution in which the solid concentration was adjusted to 50 wt %. When the weight average molecular weight was measured by a GPC method, it was 1050.

### Resin B:

### Synthesis of 3-acetoxypropyl Silsesquioxane/2-norbornenyl Silsesquioxane/Methyl Silsesquioxane Copolymer

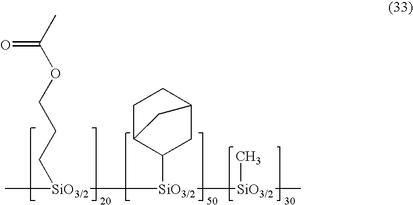

(20:50:30 in the structural formula represents a molar ratio of starting materials used)

38.7 g of an aimed compound was obtained in the same procedures as in the synthesis method for the resin A except for changing phenyl trimethoxysilane as the starting material described above to 39.0 g (0.151 mol) of 2-norbornenyl triethoxysilane. Further, the obtained compound was dissolved in propylene glycol monomethyl ether acetate to obtain a solution in which the solid concentration was adjusted to 50 wt %. When the weight average molecular weight was measured by the GPC method, it was 1020.

### Resin C:

### Synthesis of 3-acetoxypropyl Silsesquioxane/Phenyl Silsesquioxane Copolymer

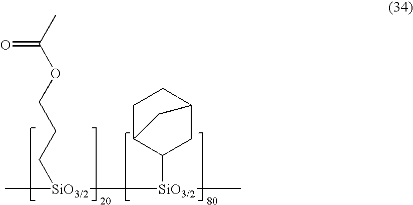

(20:80 in the structural formula represents a molar ratio of starting materials used)

Into a 500 mL four-necked flask equipped with a stirrer, a reflux condenser, a dropping funnel, and a thermometer, 38.4 g of methanol and 21.0 g of water were charged, and 1.13 g (0.0189 mol) of acetic acid was added. Then, a solution of 8.41 g (0.0378 mol) of 3-acetoxypropyl trimethoxysilane, and 30.0 g (0.151 mol) of phenyl trimethoxy silane in 19.2 g of methanol was dropped at 20 to 30° C.

After the dropping was completed, they were aged at the identical temperature for 2 hr. As a result of a GC analysis for the reaction solution, it was found that the starting materials were not left. Then, after extraction with addition of toluene and cleaning with an aqueous solution of sodium hydrogen carbonate, it was cleaned with water till the solution became neutral. A toluene oil layer was recovered, and toluene was removed to obtain 24.6 g of an aimed viscous liquid compound. Further, it was dissolved in propylene glycol monomethyl ether acetate to obtain a solution in which the solid concentration was adjusted to 50 wt %. When the weight average molecular weight was measured by the GPC method, it was 1100.

### Comparative Resin A:

### Synthesis of Phenyl Silsesquioxane

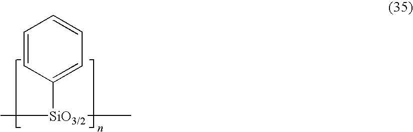

Into a 500 mL four-necked flask equipped with a stirrer, a reflux condenser, a dropping funnel, and a thermometer, 55.8 g of toluene, and 35.7 g of water were charged, and 3.12 g (0.03 mol) of 35% hydrochloric acid was added. Then, a solution of 48.0 g (0.242 mol) of phenyl trimethoxy silane in 27.9 g of toluene was dropped at 20 to 30° C. After the dropping was completed, they were aged at the identical temperature for 2 hr. As a result of the GC analysis for the reaction solution, it was found that the starting materials were not left.

After extraction with addition of toluene and water, the extracts were cleaned with an aqueous solution of sodium hydrogen carbonate and then cleaned with water till the solution became neutral. A toluene oil layer was recovered and toluene was removed to obtain 34.6 g of an aimed viscous liquid compound. Further, it was dissolved in propylene glycol monomethyl ether acetate to obtain a solution in which the solid concentration was adjusted to 50 wt %. When the weight average molecular weight was measured by the GPC method, it was 1000.

### (Synthesis of Siloxane Resin)

To a 2000 mL four-necked flask with equipped with a stirrer, a reflux condenser, a dropping funnel, and a thermometer, a solution of 317.9 g of tetraethoxysilane and 247.9 g of methyl triethoxysilane dissolved in 1116.7 g of diethylene glycol dimethyl ether were charged to which 167.5 g of nitric acid adjusted to 0.644 wt % was dropped under stirring for 30 min.

After the dropping was completed and they were reacted for 3 hr, when a portion of the formed ethanol and diethylene glycol dimethyl ether was distilled off under a reduced pressure in a warm bath to obtain 740.0 g of a siloxane resin solution at a solid concentration of 25%. When the weight average molecular weight of the polysiloxane was measured by the GPC method, it was 870.

### (Synthesis of Dissolution Inhibitory Compound)

### Dissolution Inhibitory Compound B1:

The dissolution inhibitory compound B1 was synthesized by a process represented by the following chemical reaction formula:

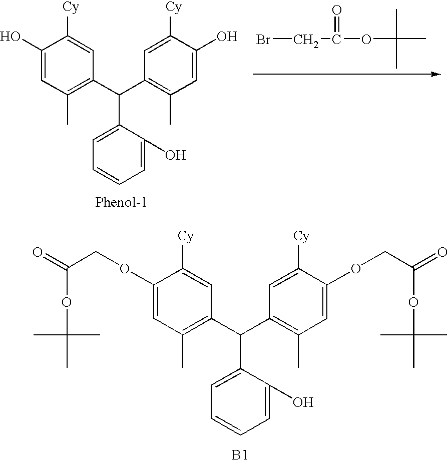

Phenol 1 (5 g) was dissolved in tetrahydrofuran (100 g) in a flask. After charging sodium hydride (3 g) therein and suspending them under a room temperature condition, a solution of t-butyl bromoacetate ester (10 g) in tetrahydrofuran (50 g) was dropped. They were reacted at 60° C. for 2 hr.

After the reaction was completed, a solid content was separated by filtration and the solvent was removed under a reduced pressure in a warm bath. Then, after dissolving concentrated residues in ethyl acetate (100 g), they were washed twice with 50 g of ion exchanged water, and the solvent was removed under a reduced pressure in a warm bath to obtain a dissolution inhibitory compound (6.5 g).

It was confirmed by high performance liquid chromatography (HPLC) that the purity of the compound obtained by purification was 90% or higher and a structure of dissolution inhibitory compound B1 was confirmed by FT-IR, ¹H-NMR, and ¹³C-MNR measurement.

### Dissolution Inhibitory Compound B2:

The dissolution inhibitory compound B2 was obtained using phenol 1 as a starting material and by way of an etherifying reaction using bromo t-butyl and potassium carbonate.

### Dissolution Inhibitory Compound B3:

The dissolution inhibitory compound B3 was obtained using phenol 1 as a starting material and by way of addition reaction of dihydropyrane to a phenolic hydroxyl group by using p-toluene sulfonic acid as a catalyst.

### Dissolution Inhibitory Compound B4:

The dissolution inhibitory compound B4 was obtained using phenol 1 as a starting material and by way of an etherifying reaction by using potassium carbonate and t-butyl bromoacetate ester.

### Dissolution Inhibitory Compounds B5, B6:

The dissolution inhibitory B5 was obtained by using phenol 2 as a starting material and the dissolution inhibitory compound B6 was obtained by using phenol 1 as a starting material, respectively by the same reaction as the synthesis method for the dissolution inhibitory compound B1.

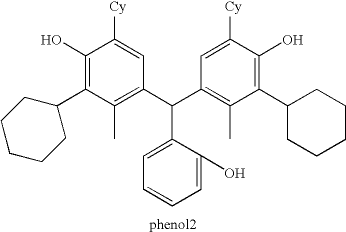

### Dissolution Inhibitory Compounds B7, B8:

The dissolution inhibitory compound B7 was obtained by using 1-methyl-1-adamantanol and 1-adamantane carboxylic acid as a starting materials by an esterifying reaction by way of an acid chloride using thionyl chloride.

The dissolution inhibitory compound B8 was obtained by using 1-methyl-1-adamantanol and 1,5-adamantane carboxylic acid as a starting materials by the same reaction as in B7.

### Dissolution Inhibitory Compound B9:

The dissolution inhibitory compound B9 was obtained by t-butyl esterifying reaction of 1-adamantane carboxylic acid.

### Dissolution Inhibitory Compound B10:

The dissolution inhibitory compound B10 was obtained by a synthesis process including three steps shown below.

(Step 1) Step 1 is represented by the general formula 45. 1,3,5-adamantane triol (5.0 g) was dissolved in a mixture of dimethyl sulfoxide (65 ml) and anhydrous acetic acid (30 mL). The solution was stirred for 40 hr, to which an aqueous 50 wt % solution of the sodium hydroxide (50 ml) was added. The mixed solution was extracted by five times with diethyl ether (50 ml).

After cleaning the extracted solution three times with an aqueous saturated solution of sodium chloride (20 ml), it was dried over anhydrous sodium sulfate. The extracted solutions were joined, filtered, and concentrated.

A transparent concentrated solution was vacuum-distilled in vacuum at 120° C. to obtain colorless oily 1,3,5-tris(methylthiomethoxy)adamantane (4 g).

(Step 2) Step 2 is represented by the general formula 46. Under a nitrogen atmosphere, 1,3,5-tris(methylthiomethoxy) adamantane (4.0 g) was dissolved in anhydrous dichloromethane (20 ml).

Thionyl chloride (3.5 ml) was diluted with anhydrous dichloromethane (10 ml) and dropped in a nitrogen atmosphere for 3 min. After stirring for 3 hr, excess thionyl chloride was evaporated by heating in vacuum. The product was dried in vacuum to obtain 1,3,5-tris(chloromethoxy)adamanatane (3.5 g) as a highly viscous oily yellow product.

(Step 3) Step 3 is represented by the general formula 47. 1,3,5-tris(chloromethoxy)adamantane (650 mg) and cholic acid (2500 mg) were dissolved in a nitrogen atmosphere in anhydrous tetrahydrofuran (30 ml). After dropping triethylamine (1.2 ml), they were stirred for 4 hr and reaction was stopped with addition of water. The mixed solution was extracted four times with diethyl ether (30 ml).

After cleaning the extracted solution three times with an aqueous saturated solution sodium chloride (20 ml) and drying the same over anhydrous sodium sulfate, an organic layer was concentrated. The product was dried in vacuum to obtain B 10 (1.10 g) as a white powder.

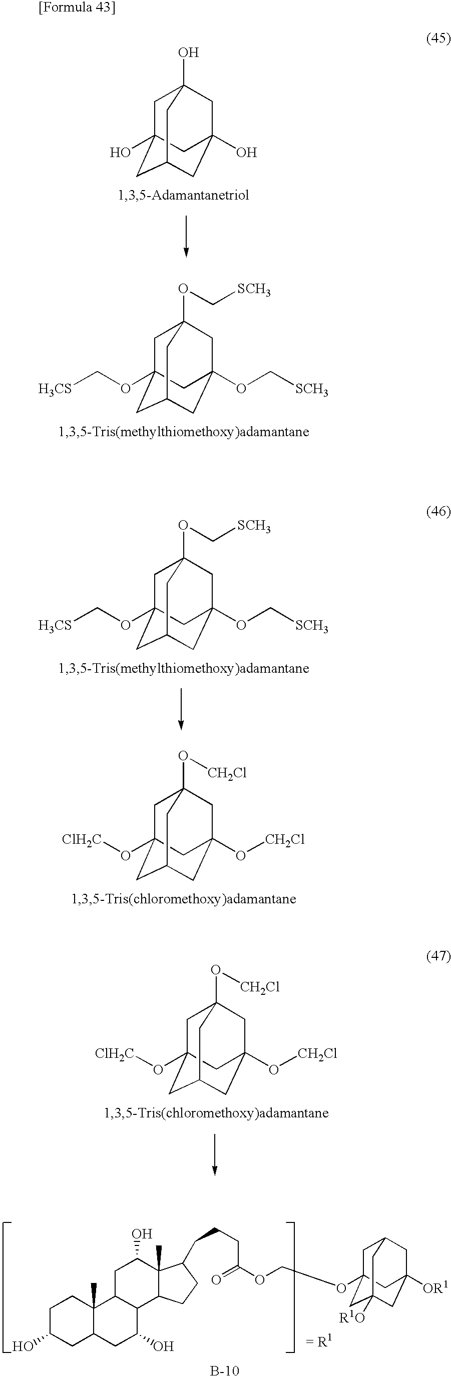

### Dissolution Inhibitory Compounds B101 to B103, B108:

The dissolution inhibitory compounds B101 to B103 and B108 could be synthesized by using the same synthesis starting materials as those for the dissolution inhibitory compound B10. This is different from the synthesis for B10 in that reaction was terminated before three hydroxyl groups were reacted completely in the reaction of step 1, the product was fractionated by column chromatography, and isomers and products of different functional numbers were separated. For the fractionation, preparative high performance liquid chromatography, preparative thin film chromatography, recrystallization, or like other method can also be used. Further, a method of not performing fractionation after the step 1 and performing fractionation after the step 3 was also applicable.

### Dissolution Inhibitory Compounds B104 to B107:

The dissolution inhibitory compounds B104 to B107 could be synthesized by using identical starting synthesis materials with those for the dissolution inhibitory compound B10 except for using 1,3-adanmantane diol (for B104, 105) or 1,5-adamantane diol (for B106, B107) instead of 1,3,5-adamantane triol. Synthesis for B105 and B107 is different from that for B10 in that the reaction was terminated before three hydroxyl groups were completely reacted in the reaction of step 1, the product was fractionated by column chromatography and isomers and products of different functional numbers were separated. For fractionation, preparative high performance liquid chromatography, preparative thin film chromatography, recrystallization, or like other method can also be used. Further, a method of not performing fractionation after the step 1 and performing fractionation after the step 3 was also applicable.

### Dissolution Inhibitory Compounds B21, B121 to B128:

The dissolution inhibitory compounds B21, B121 to B128 were synthesized in the same method as in the synthesis for B10, B101 to B108 using deoxycholic acid instead of cholic acid.

### Dissolution Inhibitory Compounds B31, B131 to B138:

The dissolution inhibitory compounds B31, B131 to B138 were synthesized in the same method as in the synthesis for B10, B101 to B108 using ursodeoxycholic acid instead of cholic acid.

### Dissolution Inhibitory Compounds B41, B141 to B148:

The dissolution inhibitory compounds B41, B141 to B148 were synthesized in the same method as in the synthesis for B10, B101 to B108 using hyodeoxycholic acid instead of cholic acid.

### Dissolution Inhibitory Compounds B51, B151 to B158:

The dissolution inhibitory compounds B51, B151 to B158 were synthesized in the same method as in the synthesis for B10, B101 to B108 using lithocholic acid instead of cholic acid.

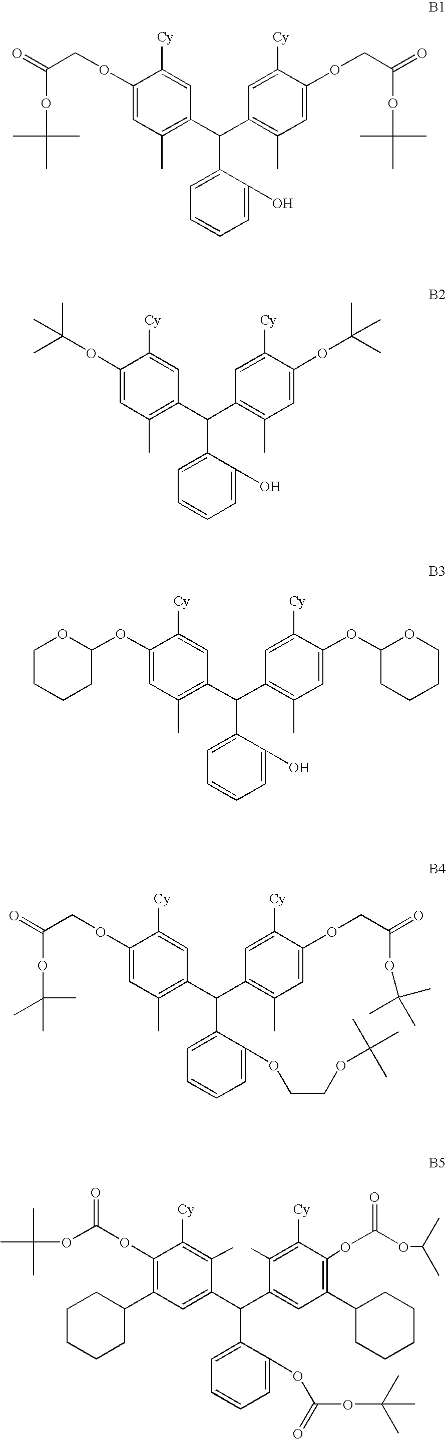

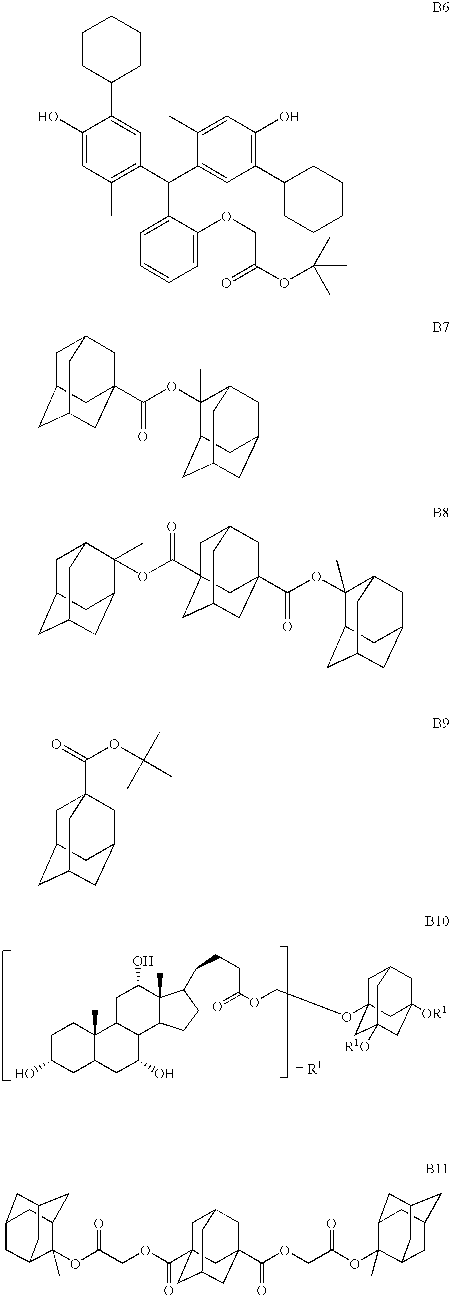

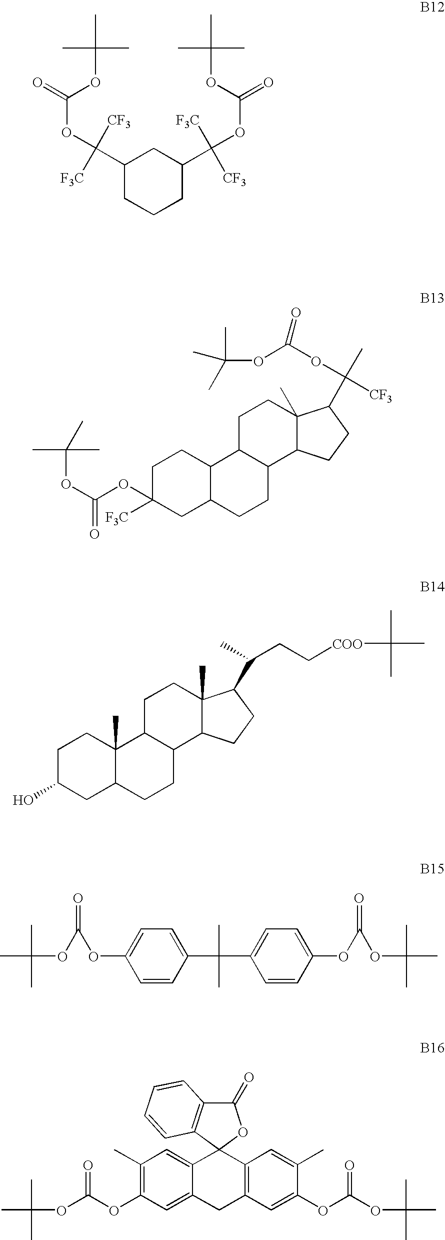

### (Preparation of Silica-Based Positive Type Photosensitive Resin Composition)

### Example 1

A siloxane resin A soluble in aqueous alkaline solution (4.2 g), a siloxane resin (3.6 g), a solution inhibitory compound B10 (0.8 g), and a photo acid generator C25 (0.05 g) were dissolved in PGMEA (80 g) to prepare a silica based positive type photosensitive resin composition A.

### Example 2

A siloxane resin B soluble in aqueous alkaline solution (4.2 g), a siloxane resin (3.6 g), a solution inhibitory compound B10 (0.8 g), and a photo acid generator C25 (0.05 g) were dissolved in PGMEA (80 g) to prepare a silica based positive type photosensitive resin composition B.

### Example 3

A siloxane resin C soluble in aqueous alkaline solution (4.2 g), a siloxane resin (3.6 g), a solution inhibitory compound B10 (0.8 g), and a photo acid generator C25 (0.05 g) were dissolved in PGMEA (80 g) to prepare a silica based positive type photosensitive resin composition C.

### Example 4

A silica based positive type photosensitive resin composition shown in Table 1 was prepared in the same manner except for changing the type of the dissolution inhibitory compound and the photo acid generator in the composition of Example 1.

### Example 5

A silica-based positive type photosensitive resin composition shown in Table 3 and Table 4 was prepared in the same manner except for changing the types of the dissolution inhibitory compound and the photo acid generator in the composition of Example 1.

### Comparative Example 1

A phenyl silsesquioxane resin (PSQ)(4.2 g), a siloxane resin (3.6 g), and 0.44 g of DNQ sulfonic acid ester compound were added respectively and dissolved under stirring at a room temperature for 30 min to prepare a silica based positive type photosensitive resin composition U.

### Comparative Example 2

A siloxane a resin A soluble in aqueous alkaline solution (4.2 g), siloxane resin (3.6 g), and a DNQ photosensitive agent (o-Naphthoquinone-diazo-5-sulfonic acid ester, product No. 68, manufactured by Respe Chemical Co., Ltd.) DNQ1 (0.8 g) were dissolved in PGMEA (80 g) to prepare a silica based positive type photosensitive resin composition V.

TABLE 1

| | Alkali- | Dis- | Photo | Silica based | Name of |
|---|---|---|---|---|---|
| | soluble | solution | acid | positive type | obtained |
| | siloxane | inhibitory | gener- | photosensitive | dielectric |
| Example | resin | compound | ator | resin | film |
| 1 | A | B10 | C25 | A | E1 |
| 2 | B | B10 | C25 | B | E2 |
| 3 | C | B10 | C25 | C | E3 |
| 4 | A | B1 | C13 | D | E4 |
| 4 | A | B2 | C13 | E | E5 |
| 4 | A | B3 | C13 | F | E6 |
| 4 | A | B4 | C13 | G | E7 |
| 4 | A | B5 | C13 | H | E8 |
| 4 | A | B6 | C13 | I | E9 |
| 4 | A | B8 | C13 | J | E10 |
| 4 | A | B8 | C13 | K | E11 |
| 4 | A | B11 | C13 | L | E12 |
| 4 | A | B12 | C13 | M | E13 |
| 4 | A | B13 | C13 | N | E14 |
| 4 | A | B14 | C13 | O | E15 |
| 4 | A | B15 | C12 | P | E16 |
| 4 | A | B16 | C12 | Q | E17 |
| 4 | A | B14 | C25 | R | E18 |
| 4 | A | B14 | C35 | S | E19 |
| 4 | A | B14 | C36 | T | E20 |
| Comp. | PSQ | B14 | C25 | U | F1 |
| Example 1 | (alkali- | | | | |
| | insoluble) | | | | |
| Comp. | A | DNQ1 | none | V | F2 |
| Example 2 | | | | | |

TABLE 3

| | Alkali- | Dis- | | Silica based | Name of |
|---|---|---|---|---|---|
| | soluble | solution | Photo | positive type | obtained |
| | siloxane | inhibitory | acid | photosensitive | dielectric |
| Example | resin | compound | generator | resin | film |
| 5 | A | B101 | C25 | A2 | E21 |
| 5 | A | B102 | C25 | B2 | E22 |
| 5 | A | B103 | C25 | C2 | E23 |
| 5 | A | B104 | C25 | D2 | E24 |
| 5 | A | B105 | C25 | E2′ | E25 |
| 5 | A | B106 | C25 | F2 | E26 |
| 5 | A | B107 | C25 | G2 | E27 |
| 5 | A | B108 | C25 | H2 | E28 |
| 5 | A | B21 | C25 | I2 | E29 |
| 5 | A | B31 | C25 | J2 | E30 |
| 5 | A | B41 | C25 | K2 | E31 |
| 5 | A | B51 | C25 | L2 | E32 |
| 5 | A | B121 | C25 | M2 | E33 |
| 5 | A | B122 | C25 | N2 | E34 |
| 5 | A | B123 | C25 | O2 | E35 |
| 5 | A | B124 | C25 | P2 | E36 |
| 5 | A | B125 | C25 | Q2 | E37 |
| 5 | A | B126 | C25 | R2 | E38 |
| 5 | A | B127 | C35 | S2 | E39 |
| 5 | A | B128 | C36 | T2 | E40 |
| 5 | A | B131 | C25 | U2 | E41 |
| 5 | A | B132 | C25 | V2 | E42 |
| 5 | A | B133 | C25 | W2 | E43 |
| 5 | A | B134 | C25 | X2 | E44 |
| 5 | A | B135 | C35 | Y2 | E45 |
| 5 | A | B136 | C36 | Z2 | E46 |
| 5 | A | B137 | C25 | A3 | E47 |
| 5 | A | B138 | C25 | B3 | E48 |

TABLE 4

| | Alkali- | Dis- | | Silica based | Name of |
|---|---|---|---|---|---|
| | soluble | solution | Photo | positive type | obtained |
| | siloxane | inhibitory | acid | photosensitive | dielectric |
| Example | resin | compound | generator | resin | film |
| 5 | A | B141 | C25 | C3 | E49 |
| 5 | A | B142 | C25 | D3 | E50 |
| 5 | A | B143 | C25 | E3 | E51 |
| 5 | A | B144 | C25 | F3 | E52 |
| 5 | A | B145 | C25 | G3 | E53 |
| 5 | A | B146 | C25 | H3 | E54 |
| 5 | A | B147 | C35 | I3 | E55 |
| 5 | A | B148 | C36 | J3 | E56 |
| 5 | A | B151 | C25 | K3 | E57 |
| 5 | A | B152 | C25 | L3 | E58 |
| 5 | A | B153 | C25 | M3 | E59 |
| 5 | A | B154 | C25 | N3 | E60 |
| 5 | A | B155 | C35 | O3 | E61 |
| 5 | A | B156 | C36 | P3 | E62 |
| 5 | A | B157 | C25 | Q3 | E63 |
| 5 | A | B158 | C25 | R3 | E64 |

### <Manufacture of Dielectric Deposition Film>

Solutions of silica based positive type photosensitive resin compositions manufactured in accordance with Examples 1 to 5 and Comparative Examples 1, and 2 were filtered by a filter made of PTFE and rotationally coated over a silicon wafer or a glass substrate for 30 sec at such a number of rotation that the film thickness after removing the solvent was 3.0 μm. Then, the solvent was removed at 150° C. for 2 min. The deposition film was exposed by way of a predetermined pattern mask at an exposure amount of 30 mJ/cm² by using PLA-600F projection exposure machine (proximity mask aligner) manufactured by Canon Inc.

Successively, they were developed with an aqueous solution of 2.38 wt % tetramethyl ammonium hydroxide at 25° C. by an immersion swinging method, cleaned with running pure water, and dried to form a pattern. Then, the patterned portion was entirely exposed at an exposure amount of 1,000 mJ/cm² by using PLA-600F proximity mask aligner manufactured by Canon Inc. Then, the deposition films were finally cured to form a dielectric deposition films in a quartz tubular furnace in which O₂ concentration was controlled to less than 1,000 ppm at 350° C. for 30 min.

### <Evaluation for Deposition Film>

Film evaluation was performed to the films deposited by the film deposition method described above by the following method.

### (Evaluation for Resolution)

Photosensitivity was evaluated for the patterned finally cured deposition films on the silicon wafers with respect to the resolution as to whether a pattern of through holes of 5 μm square was cut out or not. They were observed by using an electron microscope S-4200 (manufactured by Hitachi Instruments Service Co., Ltd.) and they were judged as “◯” in a case where the through hole pattern of 5 μm square was cut out and as “x” in a case where it was not cut out.

### [Measurement for Transmittance]

Transmittance for a light at 300 nm to 800 nm was measured by UV 3310 apparatus manufactured by Hitachi Ltd. for finally cured deposition film coated on a glass substrate having no absorption to a visible light region and it was evaluated as “◯” in a case where the transmittance at 400 nm was 97% or higher, and as “x” where it was lower than 97%.

### [Evaluation for Heat Resistance]

Film thickness after removal of the solvent and the film thickness after final curing were measured for the finally cured deposition film formed on the silicon wafer and judged as “◯” when the reduction of thickness was less than 10%, and as “x” when it was 0.10% or more. The film thickness was measured by an ellipsometer L 116B manufactured by Gartner Inc. Specifically, a film thickness obtained by irradiating an He—Ne laser on the deposition film and based on the phase difference generated by irradiation was used.

### [Evaluation for Crack Resistance]

Absence or presence of cracks in a plane was confirmed by a metal microscope under a magnification factor of 10× to 100× for the finally cured deposition film formed on the silicon wafer. It was judged as “◯” in a case where cracks were not generated and as “x” in a case where the cracks were observed.

### <Evaluation Results>

The evaluation result for the dielectric films are shown in the following Table 2, Table 5, and Table 6.

TABLE 2

| Dielectric | | | | |
|---|---|---|---|---|
| deposition | | | Heat | Crack |
| film | Resolution | Transmittance | resistance | resistance |
| E1 | ◯ | ◯ | ◯ | ◯ |
| E2 | ◯ | ◯ | ◯ | ◯ |
| E3 | ◯ | ◯ | ◯ | ◯ |
| E4 | ◯ | ◯ | ◯ | ◯ |
| E5 | ◯ | ◯ | ◯ | ◯ |
| E6 | ◯ | ◯ | ◯ | ◯ |
| E7 | ◯ | ◯ | ◯ | ◯ |
| E8 | ◯ | ◯ | ◯ | ◯ |
| E9 | ◯ | ◯ | ◯ | ◯ |
| E10 | ◯ | ◯ | ◯ | ◯ |
| E11 | ◯ | ◯ | ◯ | ◯ |
| E12 | ◯ | ◯ | ◯ | ◯ |
| E13 | ◯ | ◯ | ◯ | ◯ |
| E14 | ◯ | ◯ | ◯ | ◯ |
| E15 | ◯ | ◯ | ◯ | ◯ |
| E16 | ◯ | ◯ | ◯ | ◯ |
| E17 | ◯ | ◯ | ◯ | ◯ |
| E18 | ◯ | ◯ | ◯ | ◯ |
| E19 | ◯ | ◯ | ◯ | ◯ |
| E20 | ◯ | ◯ | ◯ | ◯ |
| F1 | X | ◯ | X | ◯ |
| F2 | ◯ | X | ◯ | ◯ |

TABLE 5

| Dielectric | | | | |
|---|---|---|---|---|
| deposition | | | Heat | Crack |
| film | Resolution | Transmittance | resistance | resistance |
| E21 | ◯ | ◯ | ◯ | ◯ |
| E22 | ◯ | ◯ | ◯ | ◯ |
| E23 | ◯ | ◯ | ◯ | ◯ |
| E24 | ◯ | ◯ | ◯ | ◯ |
| E25 | ◯ | ◯ | ◯ | ◯ |
| E26 | ◯ | ◯ | ◯ | ◯ |
| E27 | ◯ | ◯ | ◯ | ◯ |
| E28 | ◯ | ◯ | ◯ | ◯ |
| E29 | ◯ | ◯ | ◯ | ◯ |
| E30 | ◯ | ◯ | ◯ | ◯ |
| E31 | ◯ | ◯ | ◯ | ◯ |
| E32 | ◯ | ◯ | ◯ | ◯ |
| E33 | ◯ | ◯ | ◯ | ◯ |
| E34 | ◯ | ◯ | ◯ | ◯ |
| E35 | ◯ | ◯ | ◯ | ◯ |
| E36 | ◯ | ◯ | ◯ | ◯ |
| E37 | ◯ | ◯ | ◯ | ◯ |
| E38 | ◯ | ◯ | ◯ | ◯ |
| E39 | ◯ | ◯ | ◯ | ◯ |
| E40 | ◯ | ◯ | ◯ | ◯ |
| E41 | ◯ | ◯ | ◯ | ◯ |
| E42 | ◯ | ◯ | ◯ | ◯ |
| E43 | ◯ | ◯ | ◯ | ◯ |
| E44 | ◯ | ◯ | ◯ | ◯ |
| E45 | ◯ | ◯ | ◯ | ◯ |
| E46 | ◯ | ◯ | ◯ | ◯ |
| E47 | ◯ | ◯ | ◯ | ◯ |
| E48 | ◯ | ◯ | ◯ | ◯ |

TABLE 6

| Dielectric | | | | |
|---|---|---|---|---|
| deposition | | | Heat | Crack |
| film | Resolution | Transmittance | resistance | resistance |
| E49 | ◯ | ◯ | ◯ | ◯ |
| E50 | ◯ | ◯ | ◯ | ◯ |
| E51 | ◯ | ◯ | ◯ | ◯ |
| E52 | ◯ | ◯ | ◯ | ◯ |
| E53 | ◯ | ◯ | ◯ | ◯ |
| E54 | ◯ | ◯ | ◯ | ◯ |
| E55 | ◯ | ◯ | ◯ | ◯ |
| E56 | ◯ | ◯ | ◯ | ◯ |
| E57 | ◯ | ◯ | ◯ | ◯ |
| E58 | ◯ | ◯ | ◯ | ◯ |
| E59 | ◯ | ◯ | ◯ | ◯ |
| E60 | ◯ | ◯ | ◯ | ◯ |
| E61 | ◯ | ◯ | ◯ | ◯ |
| E62 | ◯ | ◯ | ◯ | ◯ |
| E63 | ◯ | ◯ | ◯ | ◯ |
| E64 | ◯ | ◯ | ◯ | ◯ |

As can be seen from Table 2, Table 5, and Table 6, each of the examples of the invention is superior to the comparative examples in overall characteristics in view of the resolution, the transmittance, the heat resistance, and the crack resistance.

### Embodiment 2

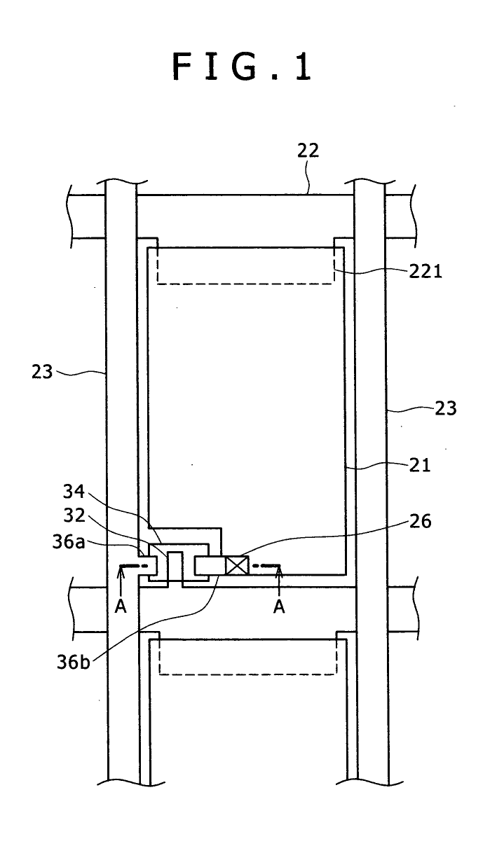

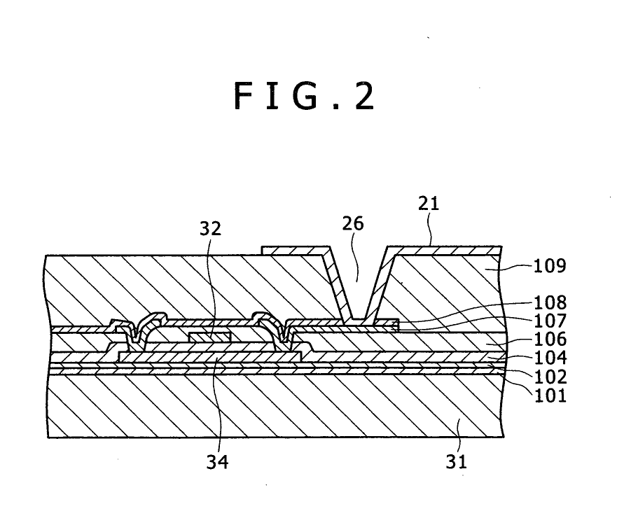

FIG. 1 and FIG. 2 show an example of applying the invention to a liquid crystal display device. FIG. 1 is a plan view for a pixel formed on a TFT substrate 31 of a liquid crystal display device. A portion surrounded by two gate lines 22 and two source lines 23 is a pixel region. Such a pixel is formed as a matrix on the glass TFT substrate 31. A color filter substrate made of glass having a common electrode (not illustrated) formed thereover and supplied with a constant voltage is disposed being opposed to the TFT substrate while sandwiching liquid crystals between them. A pixel electrode 21 including ITO occupies a most portion of the pixel region, and a TFT for controlling signals supplied to the pixel electrode is formed left below the pixel region. Liquid crystal is driven by an electric field between the pixel electrode 21 and the common electrode to form an image. A portion 221 of the gate line extends toward the pixel electrode and forms an additional capacitance while sandwiching the dielectric film between the extended portion and the pixel electrode 21.

FIG. 2 shows a cross sectional structure of the TFT. The TFT in this example is a so-called top gate type TFT. Above the glass substrate 31, two layered films including an SiN film 101 and an SiO₂ film 102 are formed as an underlying film. Each of them is disposed for preventing contamination of a semiconductor layer by impurities from the glass substrate 31. An a-Si film is formed as a semiconductor layer 34 above the underlying film. The a-Si film is sometimes transformed into a polysilicon film, for example, by using an excimer laser. A gate dielectric 104 is formed with SiO₂ or SiN above the semiconductor layer 34. For example, MoW is formed as a gate electrode layer by sputtering above the gate dielectric 104. After forming MoW by sputtering, a gate electrode 32 is formed by a photolithographic method, and an N⁺ region is formed to a semiconductor layer by ion implantation using the gate electrode 32 as a mask, thereby forming source and drain regions.

An interlayer dielectric 106 is formed, for example, with SiO₂ or SiN above the gate line layer including the gate electrode 32. After forming a through hole 26 to the interlayer dielectric 106 for establishing electric contact, a stacked film formed of Al—Si, MoW or the like is deposited by sputtering, and a source/drain electrode 107, a source line 23, etc. are formed by photolithography. Then, an inorganic passivation film 108 is formed by SiN for protecting the TFT.

An organic passivation layer 109 is formed by using a dielectric film of the invention for covering the inorganic passivation film 108 to planarize the surface. The radiation sensitive composition of the invention is used for the organic passivation film 109. The method of forming the dielectric film is also identical with that explained for Example 1. Since the organic film of the invention itself is a photosensitive film, a contact hole 26 can be formed directly without using a resist. Further, since the transmittance is excellent, brightness of an image can be improved.

Then, ITO is formed by sputtering to form a pixel electrode 21. A signal voltage is applied to the pixel electrode 21 by way of the contact hole 26. A not illustrated alignment film is formed covering the pixel electrode 21.

One of the purposes of the organic passivation film 109 in this example is to planarize the side of the liquid crystal layer, and the dielectric according to the invention can be formed to a thickness of about 2 μm and has an excellent planarizing property. Further, since the organic passivation film 109 in this example is formed also below the pixel electrode 21, high transparency is necessary. Since the dielectric film of the invention has high transparency, it is suitable as the organic passivation material as in this example.

In the foregoing description, while the dielectric film of the invention has been explained that the film is most suitable when it is used as the organic passivation film 109, the dielectric film can also be used as the gate dielectric 104 and the interlayer dielectric 106.

### Embodiment 3

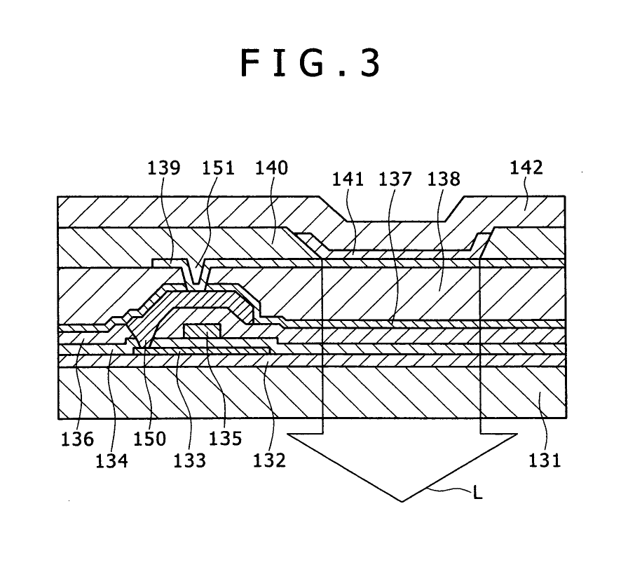

FIG. 3 shows an example of utilizing the invention to an organic EL display device. FIG. 3 is a cross sectional view for a pixel of an organic EL display device. In FIG. 3, an underlayer film 132 is formed on a glass substrate 131, and a semiconductor layer 133 as a portion of a TFT is formed above the underlayer film 132. A gate dielectric 134 is formed while covering the semiconductor layer 133, and a gate electrode 135 is formed above the gate dielectric 134. An interlayer dielectric 136 is formed while covering the gate electrode 135. A source/drain (SD) line 137 coplanar with a source line is formed above the interlayer dielectric 136. The SD line layer 137 is connected with a drain portion of the semiconductor layer through a contact hole 150 formed in the interlayer dielectric 136 and the gate dielectric 134. An inorganic passivation film 137 for protecting the TFT is formed of SiN while covering the SD wiring 136. The inorganic passivation film 137 may be sometime saved in a case of forming an organic passivation film 137 to be described below.

An dielectric film of the invention is formed as an organic passivation film 138 on the inorganic passivation film 137 for planarization. The radiation sensitive composition (A2) of the invention is used for the organic film in the same manner as in Example 4. The method of forming the dielectric film is also identical with that in Example 4. The organic film passivation film 138 is formed at a thickness from 1 μm to 2 μm. While it is necessary to form a contact hole in the organic passivation film 138, since the organic film of the invention is photosensitive by nature, the contact hole can be formed directly without using a resist. When the inorganic passivation film 137 is also formed, a contact hole 151 can be formed in the inorganic passivation film 137 by using the organic passivation film 138 as a mask. Further, since the contact hole 151 can be formed above the TFT when the dielectric film including the radiation sensitive composition of the invention is used, a light emission area of the organic EL film can be increased.

An ITO film is formed as a lower electrode 139 of an organic EL layer 141 on the organic passivation film 138. The ITO film 139 in this case is an anode of the organic EL layer 141. After forming the lower electrode 139, a bank 140 is formed by an organic film for distinguishing the pixels from each other. While a polyimide, an acrylic resin or the like has been used so far as the material for the bank 140, the organic film of the invention is a material suitable also as the bank 140. The organic film as the bank 140 is formed over the entire surface of the pixel, and removed by etching while leaving the bank 140. Since the organic film of the invention per se has a photosensitivity by nature, etching can be performed without using a resist.

A portion removed by etching is a portion for forming the pixel, and the organic EL layer 141 is formed to the portion by vapor deposition. The organic EL layer 141 is formed of plural layers including a hole injection layer, a hole transport layer, a light emission layer, an electron transport layer, an electron injection layer, etc. from the side of the lower electrode 139. An upper electrode 142 is formed, for example, with Al or Al alloy above the inorganic EL layer 141. In this case, the upper electrode 142 is a cathode. While a light emitted from the inorganic EL layer 141 is directed to the direction (bottom) shown by an arrow L, a light directing toward the upper portion in the FIG. 3 is reflected at the upper electrode 142 and is directed also to the direction (bottom) of the arrow L.

The organic passivation film 138 is used for planarization and, for this purpose, it has to be formed to a thickness of about 2 μm. On the other hand, in a bottom emission type, a light emitted from the organic EL layer 141 transmits through the organic passivation film 138 and forms an image. Accordingly, it is necessary that the organic passivation film 138 has a high transmittance. Since the organic film according to the invention has a high transmittance, this is a material suitable to the organic EL display device. Since the organic passivation film 138 has high transmittance, even when UV-ray is not irradiated, this is particularly useful for the process of the organic EL display device. While it has been explained that the organic film of the invention is used both for the passivation film and the bank, it will be apparent that the organic film may be used only for one of them.

While the dielectric film of the invention has been explained as an optimum example to a case where it is used as the organic passivation film 138 or the bank 140, it can be used also for the gate dielectric 134 and the interlayer dielectric 136.

The organic EL display device used for the explanation described above has been described as a so-called bottom emission type organic EL display device in which the light emitted from the organic EL layer is directed toward the glass substrate 131. However, the invention is not limited to such a type but it will be apparent that the invention is applicable also to a so-called top emission type organic EL display device in which a light emitted from the organic EL layer is directed to the side opposite to the glass substrate 131.

### Embodiment 4

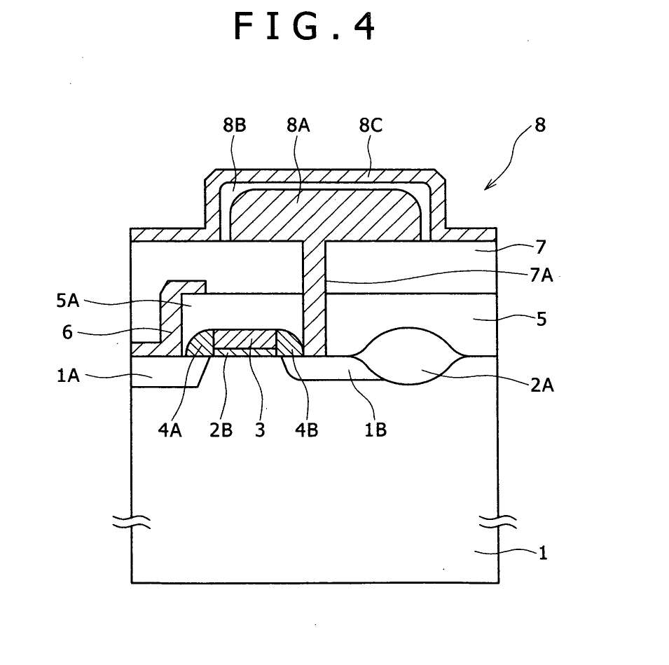

FIG. 4 is a schematic cross sectional view showing an embodiment of an electronic part according to the invention. A memory capacitor cell 8 (electronic part) has a structure in which interlayer dielectrics 5, 7 of a dual layered structure (dielectric deposition film) is formed between a gate electrode 3 (that functions as a word line) disposed by way of a gate dielectric 2B including an oxide film above a silicon wafer 1 (substrate) having diffusion regions 1A and 1B formed thereon and a counter electrode 8C disposed above the gate electrode. Side wall oxide films 4A, 4B are formed on the side walls of the gate electrode 3, and a field oxide film 2A is formed in a diffusion layer 1B on the side of the gate electrode for device isolation.

The interlayer dielectric 5 is deposited above the gate electrode 3 and the field oxide film 2A, and it is formed by spin coating the composition for forming the silica based deposition film of the invention. A contact hole 5A which contains an electrode 6 buried therein and functions as a bit line is formed in the interlayer dielectric 5 near the gate electrode 3. Further, a planarized interlayer dielectric 7 is deposited on the planarized interlayer dielectric 5, and an accumulation electrode 8A is buried in a contact hole 7A which is formed so as to penetrate both of the dielectrics. The interlayer dielectric 7 is formed by spin coating the composition for forming the silica based deposition film of the invention in the same manner as the interlayer dielectric 5. Then, the counter electrode 8C is disposed above the accumulation electrode 8A by way of a capacitor dielectric film 8B including a high dielectric material. The interlayer dielectrics 5, 7 may have an identical composition or may have different compositions.

What is claimed is:

1. A silica based positive type photosensitive resin composition containing:
an ingredient (a): a siloxane resin soluble in aqueous alkaline solution obtained by hydrolysis-condensation of a compound represented by the following general formula (1):
R¹OCOASiX₃ (1)
(in which R¹ and A each represent an organic group and X represents a hydrolyzable group),
an ingredient (b): a dissolution inhibitory compound having a functional group that can be decomposed by the action of an acid and increasing the solubility to an alkaline developer by the action of the acid,
an ingredient (c): an acid generator which is a compound generating an acid by the irradiation of a light or an electron beam, and
an ingredient (d): a solvent capable of dissolving the ingredient (a), each of the ingredients including at least one member respectively in which the blending ratio of the ingredient (a) in the composition is from 5 to 50% by weight.

2. The silica based positive type photosensitive resin composition according to claim 1,
wherein the siloxane resin soluble in aqueous alkaline solution of the ingredient (a) is obtained by hydrolysis-condensation of the compound of the general formula (1), and a compound represented by the following general formula (2):
R²SiX₃ (2)
(in which R² represents an aromatic or alicyclic hydrocarbon group or an organic group having 1 to 20 carbon atoms, and X represents a hydrolyzable group).

3. The silica based positive type photosensitive resin composition according to claim 1, wherein the siloxane resin soluble in aqueous alkaline solution of the ingredient (a) and, further, a resin obtained by hydrolysis-condensation of a compound represented by the following general formula (3) are mixed:
R³ₙSiX₄₋ₙ (3)
(in which R³ represents a group containing an H atom, an F atom, a B atom, an N atom, an Al atom, a P atom, an Si atom, a Ge atom, or a Ti atom, or an organic group having 1 to 20 carbon atoms, X represents a hydrolyzable group, n represents an integer of 0 to 2, and each X may be identical or different at n=0 to 2).

4. The silica based positive type photosensitive resin composition according to claim 1, wherein the solvent capable of dissolving the ingredient (a) contains one or more of solvents selected from the group consisting of ether acetate solvents, ether solvents, acetate solvents, alcohol solvents, and ketone solvents.

5. The silica based positive type photosensitive resin composition according to claim 1, wherein the functional group that can be decomposed by the action of the acid in the dissolution inhibitory compound of the ingredient (b) is a protection carboxyl group represented by the following general formula (8): 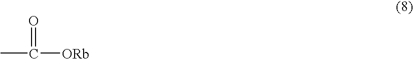
(in the general formula (8), Rb represents a dissolution inhibitory group, which is a functional group selected from a tetrahydropyranyl group, a tetrahydrofranyl group, a methoxyethoxymethyl group, a benzoyloxymethyl group, a t-butyl group, a dicyclopropyl methyl group, a 2,4-dimethyl 3-pentyl group, a cyclopentyl group, a cyclohexyl group, a p-methoxybenzyl group, a trimethyl silyl group, a triethyl silyl group, a t-butyl dimethyl silyl group, a t-butyl diphenyl silyl group, a triisopropyl silyl group, a methyl carbonate group, a 1-adamantyl carbonate group, a t-butyl carbonate group (t-BOC group), and an allylvinyl carbonate group).

6. The silica based positive type photosensitive resin composition according to claim 1, wherein the functional group that can be decomposed by the action of the acid in the dissolution inhibitory compound of the ingredient (b) is a protection carboxyl group represented by the following general formula (41): 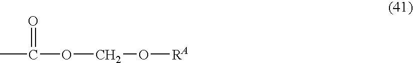
(in the general formula (41), R^{A} is a functional group selected from substituted or not-substituted linear or branched alkyl groups having 1 to 30 carbon atoms, and substituted or not-substituted cycloalkyl groups having 1 to 30 carbon atoms).

7. The silica based positive type photosensitive resin composition according to claim 1, wherein the substituted or not-substituted cycloalkyl groups having 1 to 30 carbon atoms according to claim 6 are represented by the following general formula (42): 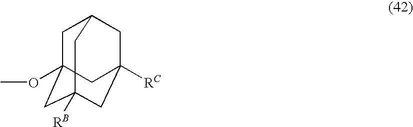
(in the general formula (42), R^{B} and R^{C} each represent a functional group selected from a hydrogen atom, a hydroxyl group, and an alkyl ether group having 1 to 30 carbon atoms).

8. The silica based positive type photosensitive resin composition according to claim 1,
wherein the functional group that can be decomposed by the action of the acid in the dissolution inhibitory compound of the ingredient (b) is bonded to the compound of the following general formula (43): 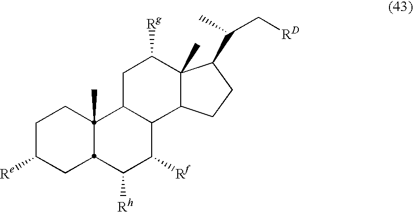
(in the general formula (43), R^{e} is a functional group represented by the general formula (41) that can be decomposed by the action of the acid (in the general formula (41), R^{A} is a functional group selected from substituted or not-substituted linear or branched alkyl groups having 1 to 30 carbon atoms and substituted or not-substituted cycloalkyl groups having 1 to 30 carbon atoms)), R^{e}, R^{f}, R^{g} and R^{e} are functional groups each selected from a hydrogen atom, a hydroxyl group, alkyl ether groups having 1 to 10 carbon atoms, and an acetoxy ether group).

9. The silica based positive type photosensitive resin composition according to claim 1,
wherein the functional group that can be decomposed by the action of the acid in the dissolution inhibitory compound of the ingredient (b) is a protection phenolic hydroxyl group represented by the following the general formula (7): 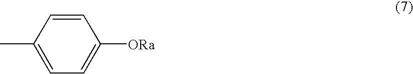
(in the general formula (7), Ra represents a dissolution inhibitory group, which is a functional group selected from a methoxymethyl group, a benzoyloxymethyl group, a methoxyethoxymethyl group, a 2-(trimethyl silyl)ethoxymethyl group, a methylthiomethyl group, a tetrahydropyranyl group, a 1-ethoxyethyl group, a phenacyl group, a cyclopropyl group, an isopropyl group, a cyclohexyl group, a t-butyl group, a trimethyl silyl group, a t-butyl dimethylsilyl group, a t-butyl diphenyl silyl group, a triisopropyl silyl group, a methyl carbonate group, a 1-adamantyl carbonate group, a t-butyl carbonate group (t-BOC group), and an allylvinyl carbonate group).

10. The silica based positive type photosensitive resin composition according to claim 1, wherein the dissolution inhibitory compound of the ingredient (b) is a compound having an alicyclic group having a molecular weight of from 200 to 2000.

11. The silica based positive type photosensitive resin composition according to claim 7, wherein the alicyclic group is an adamantyl group.

12. The silica based positive type photosensitive resin composition according to claim 1, wherein the acid generator of the ingredients (c) is an acid generator that generates hydrohalogenic acid or sulfonic acid by the irradiation of the light.

13. A method of forming a silica based dielectric deposition film comprising the steps of:
forming a coating film by coating, on a substrate, a silica based positive type photosensitive resin composition containing:
an ingredient (a) a siloxane resin soluble in aqueous alkaline solution obtained by hydrolysis-condensation of a compound represented by the following general formula (1):
R¹OCOASiX₃ (1)
(in which R¹ and A each represent an organic group and X represents a hydrolyzable group),
an ingredient (b): a dissolution inhibitory compound having a functional group that can be decomposed by the action of an acid and increasing the solubility to an alkaline developer by the action of the acid,
an ingredient (c): an acid generator which is a compound generating an acid by the irradiation of a light or an electron beam, and
an ingredient (d): a solvent capable of dissolving the ingredient (a), each of the ingredients including at least one member respectively in which the blending ratio of the ingredient (a) in the composition is from 5 to 50% by weight;
removing the organic solvent contained in the coating film;
removing the deposition film at an exposed region by performing exposure and development to the deposition film by way of a pattern mask; and
subjecting the remaining deposition film to a heating treatment.

14. The method of forming a silica based dielectric deposition film according to claim 11, wherein the deposition film is obtained by further performing exposure after removing the deposition film for the exposed region and then subjecting the remaining deposition film to the heating treatment.

15. A liquid crystal display device in which a thin film transistor is formed above a substrate, an organic dielectric film is formed covering the thin film transistor, and a pixel electrode is formed above the organic dielectric,
wherein the organic dielectric film is a silica based positive type photosensitive resin containing:
an ingredient (a): a siloxane resin soluble in aqueous alkaline solution obtained by hydrolysis-condensation of a compound represented by the following general formula (1):
R¹OCOASiX₃ (1)
(in which R¹ and A each represent an organic group and X represents a hydrolyzable group),
an ingredient (b): a dissolution inhibitory compound having a functional group that can be decomposed by the action of an acid and increasing the solubility to an alkaline developer by the action of the acid,
an ingredient (c): an acid generator which is a compound generating an acid by the irradiation of a light or an electron beam, and
an ingredient (d): a solvent capable of dissolving the ingredient (a), each of the ingredients including at least one member respectively in which the blending ratio of the ingredient (a) in the composition is from 5 to 50% by weight.
